(19) United States
(12) Patent Application Publication
(10) Pub. No.: US 2026/0252441 A1
(43) Pub. Date: Aug. 27, 2026

(54) SEMICONDUCTOR MEMORY DEVICES

(71) Applicant: SAMSUNG ELECTRONICS CO., LTD., Suwon-si (KR)

(72) Inventors: Donggeun LEE, Suwon-si (KR); Sungrae KIM, Suwon-si (KR); Donggun AN, Suwon-si (KR)

(73) Assignee: SAMSUNG ELECTRONICS CO., LTD., Suwon-si (KR)

(21) Appl. No.: 19/385,688

(22) Filed: Nov. 11, 2025

(30) Foreign Application Priority Data
Feb. 26, 2025 (KR) 10-2025-0024794

(51) Int. Cl. G06F 11/10

(52) U.S. Cl. CPC G06F 11/1048; G06F 11/1016

(57) ABSTRACT

A semiconductor memory device includes a memory cell array, an on-die error correction code (ECC) engine, a link ECC engine. The link ECC engine, in a write operation, receives a first codeword including a first main data and a first link parity data from a memory controller, generates a first syndrome including a plurality of syndrome bits based on the first codeword and a first parity check matrix that is based on a first ECC, generate a decoding status flag indicating whether a transmission error is detected in the first codeword using a characteristic of the first syndrome based on a regularity of the first parity check matrix while decoding the first syndrome, corrects an error bit of the first codeword based on the decoded first syndrome, and provides the first main data of the first codeword, which is corrected, to the on-die ECC engine.

### CROSS-REFERENCE TO RELATED APPLICATION

This application claims priority under 35 U.S.C. § 119 to Korean Patent Application No. 10-2025-0024794, filed on Feb. 26, 2025, in the Korean Intellectual Property Office (KIPO), the disclosure of which is incorporated herein by reference in its entirety.

### BACKGROUND

The present disclosure relates to memories, and more particularly to semiconductor memory devices that reduce decoding latency.

High speed operation and cost efficiency of a volatile memory device such as a dynamic random access memory DRAM make it possible for DRAMs to be used for system memories. Due to the continuing shrink in fabrication design rule of DRAMs, bit errors of memory cells in the DRAMs may rapidly increase and yield of the DRAMs may decrease. Therefore, there is a need for enhancing reliability of the semiconductor memory device.

Recently, the DRAM includes an error correction code (ECC) engine for increasing reliability of data. The ECC engine may correct at least one error bit in the data. The DRAM may provide a decoding result of the ECC engine as a decoding status flag to an external device (e.g., a memory controller).

### SUMMARY

Some example embodiments provide a semiconductor memory device capable of generating a decoding status flag with reducing decoding latency.

According to example embodiments, a semiconductor memory device includes a memory cell array, an on-die error correction code (ECC) engine, a link ECC engine and a control logic circuit. The memory cell array includes a plurality of memory cells coupled to a plurality of word-lines and a plurality of bit-lines. The control logic circuit controls the on-die ECC engine and the link ECC engine. The link ECC engine, in a write operation, receives a first codeword including a first main data and a first link parity data from a memory controller external to the semiconductor memory device, generates a first syndrome including a plurality of syndrome bits based on the first codeword and a first parity check matrix that is based on a first ECC, generates a decoding status flag indicating whether a transmission error which occurs during the first codeword is being transmitted from the memory controller, is detected in the first codeword using a characteristic of the first syndrome based on a regularity of the first parity check matrix while decoding the first syndrome, corrects an error bit of the first codeword based on the decoded first syndrome, and provides the first main data of the first codeword, which is corrected, to the on-die ECC engine. The on-die ECC engine, in the write operation, generate a parity data by performing a first ECC encoding on the first main data based on a second ECC, and stores the first main data and the parity data in a target page of the memory cell array.

According to example embodiments, a semiconductor memory device includes a memory cell array, an on-die error correction code (ECC) engine, a link ECC engine and a control logic circuit. The memory cell array includes a plurality of memory cells coupled to a plurality of word-lines and a plurality of bit-lines. The control logic circuit controls the on-die ECC engine and the link ECC engine. The link ECC engine, in a write operation, receives a first codeword including a first main data and a first link parity data from a memory controller external to the semiconductor memory device, corrects a transmission error, which occurs during the first codeword is being transmitted from the memory controller, in the first codeword by performing a first ECC decoding on the first codeword based on a first ECC, and provides the first main data of the first codeword, which is corrected, to the on-die ECC engine. The on-die ECC engine, in the write operation, generates a parity data by performing a first ECC encoding on the first main data based on a second ECC and stores the first main data and the parity data in a target page of the memory cell array. The on-die ECC engine, in a read operation, generates a syndrome including a plurality of syndrome bits based on the first main data, the parity data and a parity check matrix is based on the second ECC, the first main data and the parity data read from the target page, generates a decoding status flag indicating whether an error is detected in the first main data and the parity data using a characteristic of the syndrome based on a regularity of the parity check matrix while decoding the syndrome, generates a second main data by correcting an error bit of the first main data based on the decoded syndrome, and provides the second main data to the link ECC engine.

According to example embodiments, a semiconductor memory device includes a memory cell array, an on-die error correction code (ECC) engine and a control logic circuit. The memory cell array includes a plurality of memory cells coupled to a plurality of word-lines and a plurality of bit-lines. The control logic circuit controls the ECC engine. The ECC engine, in a write operation, receives a first main data from a memory controller external to the semiconductor memory device, generates a parity data by performing an ECC encoding on the first main data based on an ECC and stores the first main data and the parity data in a target page of the memory cell array. The ECC engine, in a read operation, reads the first main data and the parity data form the target page, generates a syndrome including a plurality of syndrome bits based on the first main data, the parity data and a parity check matrix, that is based on the ECC, generates a decoding status flag indicating whether an error is detected in the first main data and the parity data using a characteristic of the syndrome based on a regularity of the parity check matrix while decoding the syndrome, generates a second main data by correcting an error bit of the first main data based on the decoded syndrome, and transmits the second main data to the memory controller.

According to example embodiments, there is provided a method of operating a semiconductor memory device including a memory cell array, an on-die error correction code (ECC engine) and a link ECC engine. According to the method, a first codeword including a first main data and a first link parity data is received, by the link ECC engine, rom a memory controller, a first syndrome including a plurality of syndrome bits is generated, by the link ECC engine based on the first codeword and a first parity check matrix that is based on a first ECC, a decoding status flag indicating whether a transmission error which occurs during the first codeword is being transmitted from the memory controller, is detected in the first codeword, is generated by the link ECC decoder, by using a characteristic of the first syndrome based on a regularity of the first parity check matrix while decoding the first syndrome, an error bit of the first codeword is corrected by the link ECC engine, based on the decoded first syndrome, and the first main data of the first codeword is provided to the on-die ECC engine. The first main data and a parity data are stored, by the on-die ECC engine, in a target page of the memory cell array.

Accordingly, the link ECC engine or the on-die ECC engine according to example embodiments, generates the syndrome, divides syndrome bits of the syndrome into a plurality of sets in parallel with decoding the syndrome, generates counted values by counting a number of syndrome bits having a logic high levels in each of the plurality of sets and generates a decoding status flag based on the counted values. When the link ECC engine or the on-die ECC engine generates the decoding status flag, a result of the syndrome decoding is not used. Therefore, the link ECC engine or the on-die ECC engine may reduce the decoding latency and may reduce occupied circuit area associated with the ECC decoding.

### BRIEF DESCRIPTION OF THE DRAWINGS

Example embodiments will be described below in more detail with reference to the accompanying drawings.

FIG. 1 is a block diagram illustrating a memory system according to example embodiments.

FIG. 2 is a block diagram illustrating an example of the memory controller in the memory system of FIG. 1 according to example embodiments.

FIG. 3 illustrates data set corresponding to a plurality of burst lengths in the memory system of FIG. 1 according to example embodiments.

FIG. 4 is a block diagram illustrating an example of the semiconductor memory device in the memory system of FIG. 1 according to example embodiments.

FIG. 5 illustrates an example of the first bank array in the semiconductor memory device of FIG. 4 according to example embodiments.

FIG. 6 illustrates a portion of the semiconductor memory device of FIG. 4.

FIG. 7 is a block diagram illustrating an example of the link ECC decoder in the link ECC engine in FIG. 6 according to example embodiments.

FIG. 8 is a block diagram illustrating an example of the link ECC encoder in the link ECC engine in FIG. 6 according to example embodiments.

FIG. 9 illustrates an example of a parity check matrix used in the link ECC engine in FIG. 6 according to some example embodiments.

FIG. 10 illustrates an example of the parity check matrix in FIG. 9 according to some example embodiments.

FIGS. 11A through 11L illustrate an example of a plurality of code groups of the parity check matrix of FIG. 10 according to example embodiments.

FIG. 12A illustrates one of the column vectors in FIGS. 11A through 11L.

FIG. 12B illustrates one of the column vectors in FIGS. 11A through 11L.

FIG. 13A is a block diagram illustrating an example of the DSF generator in FIG. 7 according to example embodiments.

FIG. 13B is a block diagram illustrating an example of the DSF generator in FIG. 7 according to example embodiments.

FIG. 14 illustrates an example of the encoding/decoding logic in the on-die ECC engine in FIG. 6 according to example embodiments.

FIG. 15 illustrates an example of the data corrector in the on-die ECC engine in FIG. 6 according to example embodiments.

FIG. 16 illustrates a portion of the semiconductor memory device of FIG. 4 according to example embodiments.

FIG. 17 is a flow chart illustrating a method of operating a semiconductor memory device according to example embodiments.

FIG. 18 is a block diagram illustrating a memory system according to example embodiments.

FIG. 19 is a block diagram illustrating an example of the semiconductor memory device in the memory system of FIG. 18 according to example embodiments.

FIG. 20 illustrates a portion of the semiconductor memory device of FIG. 19.

FIG. 21 is a block diagram illustrating an example of the ECC decoder in the on-die ECC engine in FIG. 20 according to example embodiments.

FIG. 22 is a flow chart illustrating a method of operating a semiconductor memory device according to example embodiments.

FIG. 23 is a block diagram illustrating a memory system according to example embodiments.

FIG. 24 is a block diagram illustrating an example of the semiconductor memory device in the memory system of FIG. 23 according to example embodiments.

FIG. 25 is a block diagram illustrating an example of the ECC engine of the semiconductor memory device of FIG. 24 according to example embodiments.

FIG. 26 is a block diagram illustrating an example of the ECC decoder in the ECC engine in FIG. 25 according to example embodiments.

FIG. 27 is a flow chart illustrating a method of operating a semiconductor memory device according to example embodiments.

FIG. 28 is a block diagram illustrating a semiconductor memory device according to example embodiments.

FIG. 29 is a diagram illustrating a semiconductor package including the stacked memory device, according to example embodiments.

### DETAILED DESCRIPTION

Various example embodiments will be described more fully hereinafter with reference to the accompanying drawings, in which example embodiments are shown.

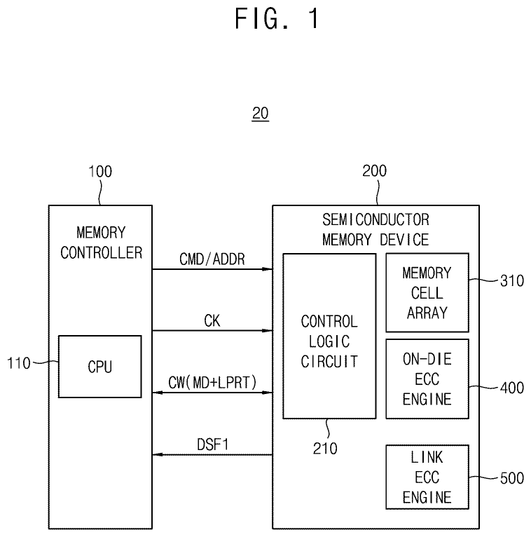

FIG. 1 is a block diagram illustrating a memory system according to example embodiments.

Referring to FIG. 1, a memory system 20 may include a memory controller 100 and a semiconductor memory device 200.

The memory controller 100 may control overall operation of the memory system 20. The memory controller 100 may control overall data exchange between an external host and the semiconductor memory device 200. For example, the memory controller 100 may write data in the semiconductor memory device 200 or read data from the semiconductor memory device 200 in response to request from the host. The memory controller 100 may be referred to as an external device.

In addition, the memory controller 100 may issue operation commands to the semiconductor memory device 200 for controlling the semiconductor memory device 200. The memory controller 100 may be referred to as an external device In some embodiments, the semiconductor memory device 200 is a memory device including dynamic memory cells such as a dynamic random access memory (DRAM), or a low power (LP) double data rate 6 (DDR6) synchronous DRAM (SDRAM).

The memory controller 100 may transmit a command CMD and an address (signal) ADDR to the semiconductor memory device 200, may transmit a clock signal CK to the semiconductor memory device 200, may transmit a codeword CW including a main data MD and a link parity data LPRT to the semiconductor memory device 200, may receive the codeword CW from the semiconductor memory device 200, and may receive a decoding status flag DSF1 from the semiconductor memory device 200.

The memory controller 100 may include a central processing unit (CPU) 110 and the CPU 110 may control overall operation of the memory controller 100.

The semiconductor memory device 200 may include a memory cell array 310 that stores the main data MD, an on-die error correction code (ECC) engine 400, a link ECC engine 500 and a control logic circuit 210.

The control logic circuit 210 may control access to the memory cell array 310 and may control the on-die ECC engine 400 and the link ECC engine 500 based on the command CMD and the address ADDR.

The link ECC engine 500, in a write operation based on a write command from the memory controller 100, may receive the codeword, may generate a first syndrome including a plurality of syndrome bits based on the codeword CW and a first parity check matrix that is based on a first ECC, may generate the decoding status flag DSF1 indicating whether a transmission error, which occurs during the first codeword is being transmitted from the memory controller 100, is detected in the codeword CW using a characteristic of the first syndrome based on a regularity of the first parity check matrix while decoding the first syndrome, may correct an error bit of the codeword CW based on the decoded first syndrome, may provide the main data of the codeword CW, which is corrected, to the on-die ECC engine 400, and may transmit the decoding status flag DSF1 to the memory controller 100.

The on-die ECC engine 400, in the write operation, may generate a parity data by performing a first ECC encoding on the main data based on a second ECC, and may store main data and the parity data in a target page of the memory cell array 310.

Therefore, because the link ECC engine 500 generates the decoding status flag DSF by using only the first syndrome, the link ECC engine 500 may reduce ECC decoding latency and an occupied area of associated circuits.

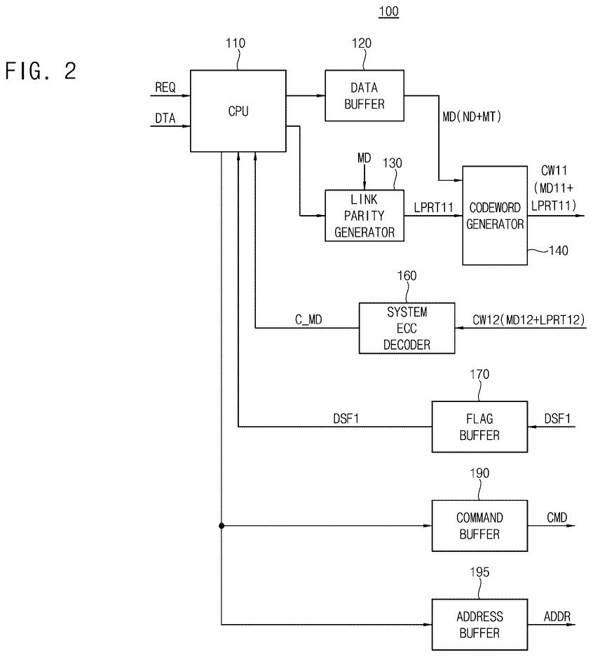

FIG. 2 is a block diagram illustrating an example of the memory controller in the memory system of FIG. 1 according to example embodiments.

Referring to FIG. 2, the memory controller 100 may include the CPU 110, a data buffer 120, a link parity generator 130, a codeword generator 140, a system ECC decoder 160, a flag buffer 170, a command buffer 190 and an address buffer 195.

The CPU 110 may receive a request REQ and a data DTA from the host, and may provide the data DTA to the data buffer 120. The CPU 110 may control the data buffer 120, the link parity generator 130, the codeword generator 140, the system ECC decoder 160, a flag buffer 170, the command buffer 190 and the address buffer 195.

The data buffer 120 may buffer the data DTA to provide the main data MD to the codeword generator 140. The main data MD may include a normal data ND and a metadata MT.

The link parity generator 130 may generate a first link parity data LPRT11 based on the main data MD and may provide the first link parity data LPRT11 to the codeword generators 140. The codeword generator 140 may generate a first codeword CW11 including a first main data MD11 corresponding to the main data MD and the first link parity data LPRT11 and may transmit the first codeword CW11 to the semiconductor memory device 200.

The system ECC decoder 160, in a read operation on the semiconductor memory device 200, may receive a second codeword CW12 including a second main data MD12 and a second link parity data LPRT12 from the semiconductor memory device 200, may correct an error bit of the second main data MD 12 by performing an ECC decoding on the second codeword CW12 and may provide a corrected main data C MD to the CPU 110.

The flag buffer 170 may receive the decoding status flag DSF1 from the semiconductor memory device 200 and may provide the decoding status flag DSF1 to the CPU 110. The CPU 110, based on the decoding status flag DSF1, may determine whether a transmission error, which is uncorrectable, occurs in the first codeword CW11 that is transmitted to the semiconductor memory device 200.

The command buffer 190 may store the command CMD corresponding to the request REQ and may transmit the command CMD to the semiconductor memory device 200 under control of the CPU 110. The address buffer 195 may store the address ADDR and may transmit the address ADDR to the semiconductor memory device 200 under control of the CPU 110.

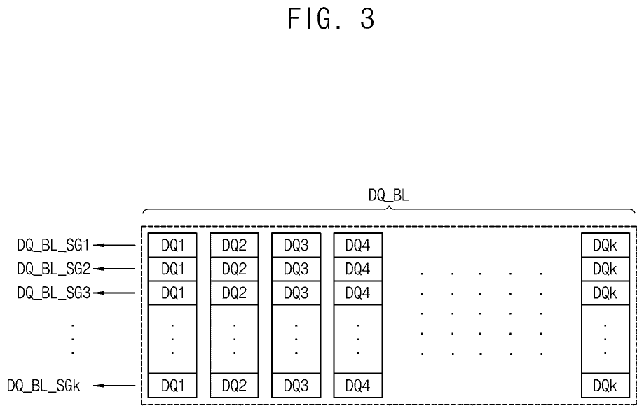

FIG. 3 illustrates data set corresponding to a plurality of burst lengths in the memory system of FIG. 1 according to example embodiments.

Referring to FIG. 3, a data set DQ_BL corresponding to a plurality of burst lengths are input to/output from the semiconductor memory device 200. The data set DQ_BL includes data segments DQ_BL_SG1, DQ_BL_SG2, DQ_BL_SG3, ..., DQ_BL_SGk each corresponding to each of the plurality of burst lengths, where k is an integer greater than three. The data set DQ_BL corresponding to the plurality of burst lengths may be stored in the memory cell array 310 of the semiconductor memory device 200. The data set DQ_BL may include the main data MD and the link parity data LPRT.

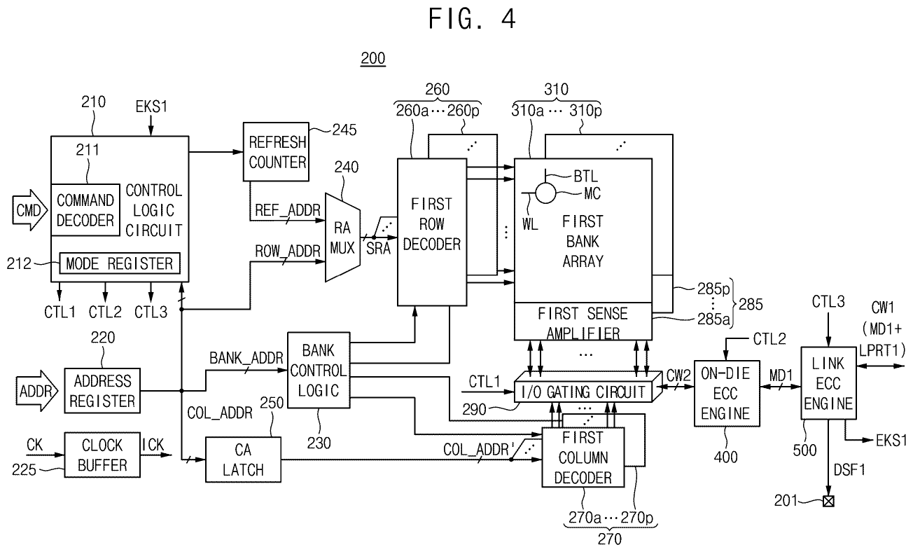

FIG. 4 is a block diagram illustrating an example of the semiconductor memory device in the memory system of FIG. 1 according to example embodiments.

Referring to FIG. 4, the semiconductor memory device 200 may include the control logic circuit 210, an address register 220, a bank control logic 230, a refresh counter 245, a row address multiplexer RA MUX 240, a column address latch 250, a row decoder 260, a column decoder 270, the memory cell array 310, a sense amplifier unit 285, an I/O gating circuit 290, the on-die ECC engine 400, a clock buffer 225 and the link ECC engine 500.

The memory cell array 310 may include first through sixteenth bank arrays 310a~310p. The row decoder 260 may include first through sixteenth row decoders 260a~260p respectively coupled to the first through sixteenth bank arrays 310a~310p, the column decoder 270 may include first through sixteenth column decoders 270a~270p respectively coupled to the first through sixteenth bank arrays 310a~310p, and the sense amplifier unit 285 may include first through sixteenth sense amplifiers 285a~285p respectively coupled to the first through sixteenth bank arrays 310a~310p.

The first through sixteenth bank arrays 310a~310p, the first through sixteenth row decoders 260a~260p, the first through sixteenth column decoders 270a~270p and first through sixteenth sense amplifiers 285a~285p may form first through sixteenth banks. Each of the first through sixteenth bank arrays 310a~310p may include a plurality of memory cells MC formed at intersections of a plurality of word-lines WL and a plurality of bit-lines BTL.

The address register 220 may receive the address ADDR including a bank address BANK ADDR, a row address ROW_ADDR and a column address COL ADDR from the memory controller 100. The address register 220 may provide the received bank address BANK ADDR to the bank control logic 230, may provide the received row address ROW ADDR to the row address multiplexer 240, and may provide the received column address COL ADDR to the column address latch 250.

The bank control logic 230 may generate bank control signals in response to the bank address BANK ADDR. One of the first through sixteenth row decoders 260a~260p corresponding to the bank address BANK ADDR is activated in response to the bank control signals, and one of the first through sixteenth column decoders 270a~270p corresponding to the bank address BANK ADDR is activated in response to the bank control signals.

The row address multiplexer 240 may receive the row address ROW ADDR from the address register 220, and may receive a refresh row address REF ADDR from the refresh counter 245. The row address multiplexer 240 may selectively output the row address ROW ADDR or the refresh row address REF ADDR as a row address SRA. The row address SRA that is output from the row address multiplexer 240 is applied to the first through sixteenth row decoders 260a~260p.

The refresh counter 245 may sequentially increase or decrease the refresh row address REF ADDR under control of the control logic circuit 210.

The activated one of the first through sixteenth row decoders 260a~260p, by the bank control logic 230, may decode the row address SRA that is output from the row address multiplexer 240, and may activate a word-line corresponding to the row address SRA. For example, the activated row decoder applies a word-line driving voltage to the word-line corresponding to the row address SRA.

The column address latch 250 may receive the column address COL_ADDR from the address register 220, and may temporarily store the received column address COL ADDR. In some embodiments, in a burst mode, the column address latch 250 may generate column address COL ADDR′ that increment from the received column address COL ADDR. The column address latch 250 may apply the temporarily stored or generated column address COL_ADDR′ to the first through sixteenth column decoders 270a~270p.

The activated one of the first through sixteenth column decoders 270a~270p, by the bank control logic 230, may activate a sense amplifier corresponding to the bank address BANK ADDR and the column address COL_ADDR through the I/O gating circuit 290.

The I/O gating circuit 290 may include a circuitry for gating input/output data, and may further include input data mask logic, read data latches for storing data that is output from the first through sixteenth bank arrays 310a~310p, and write drivers for writing data to the first through sixteenth bank arrays 310a~310p.

In a read operation, codeword CW2 read from a selected one bank array of the first through sixteenth bank arrays 310a~310p may be sensed by a sense amplifier coupled to the selected one bank array from which the data is to be read, and is stored in the read data latches. The codeword CW2 stored in the read data latches may be provided to the link ECC engine 295 as a main data MD1 after ECC decoding is performed on the codeword CW2 by the on-die ECC engine 400. The link ECC engine 500 may generate a link parity data LPRT1 by performing an ECC encoding on the main data MD1 and may transmit a codeword CW1 including the main data MD1 and the link parity data LPRT1 to the memory controller 100.

In a write operation, the link ECC engine 500 may receive the codeword CW1 including the link parity data LPRT1 and the main data MD1 to be written in a selected one bank array of the first through sixteenth bank arrays 310a~310p from the memory controller 100. The link ECC engine 500 may provide the main data MD1 to the on-die ECC engine 400 by performing an ECC decoding on the main data MD1 based on the link parity data LPRT1 to correct at least one error bit occurring during the codeword CW1 is being transmitted. The on-die ECC engine 400 may perform an ECC encoding on the main data MD1 to generate parity bits (or parity data), and the on-die ECC engine 400 may provide the codeword CW2 including main data MD1 and the parity bits to the I/O gating circuit 290. The I/O gating circuit 290 may write the codeword CW2 in a target page in the selected one bank array through the write drivers.

In the write operation, when the link ECC engine 500 performs the ECC decoding, the link ECC engine 500 may generate a first syndrome including a plurality of syndrome bits based on the codeword CW1 and the first parity check matrix that is based on a first ECC, may generate the decoding status flag DSF1 indicating whether a transmission error, which occurs during the codeword CW1 is being transmitted from the memory controller 100, is detected in the codeword CW using a characteristic of the first syndrome based on a regularity of the first parity check matrix while decoding the first syndrome, may generate an error kind signal EKS1 indicating a type of the transmission error, may correct an error bit of the codeword CW1 based on the decoded first syndrome, may provide the main data MD1 of the codeword CW1, which is corrected, to the on-die ECC engine 400, may transmit the decoding status flag DSF1 to the memory controller 100 through an alert pin 201 and may provide the error kind signal EKS1 to the control logic circuit 210. The error kind signal EKS1 may be referred to as an error type signal.

The on-die ECC engine 400 may perform an ECC encoding on the main data MD1 in the write operation and perform an ECC decoding on the codeword CW2 in a read operation, based on a second control signal CTL2 from the control logic circuit 210.

The clock buffer 225 may receive the clock signal CK, may generate an internal clock signal ICK by buffering the clock signal CK, and may provide the internal clock signal ICK to circuit components processing the command CMD and the address ADDR.

The control logic circuit 210 may control operations of the semiconductor memory device 200. For example, the control logic circuit 210 may generate control signals for the semiconductor memory device 200 in order to perform a write operation, a read operation, or a refresh operation. The control logic circuit 210 may include a command decoder 211 that decodes the command CMD received from the memory controller 100 and a mode register 212 that sets an operation mode of the semiconductor memory device 200.

For example, the command decoder 211 may generate the control signals corresponding to the command CMD by decoding a write enable signal, a row address strobe signal, a column address strobe signal, a chip select signal, etc. The control logic circuit 210 may generate a first control signal CTL1 for controlling the I/O gating circuit, the second control signal CTL2 for controlling the on-die ECC engine 400 and a third control signal CTL3 for controlling control the link ECC engine 500.

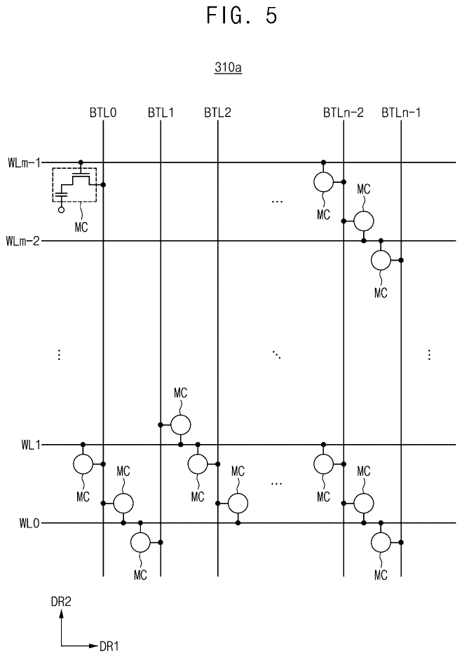

FIG. 5 illustrates an example of the first bank array in the semiconductor memory device of FIG. 4 according to example embodiments.

Referring to FIG. 5, the first bank array 310a may include a plurality of word-lines WL0~WLm-1 (m is a natural number greater than two), a plurality of bit-lines BTL0~BTLn-1 (n is a natural number greater than two), and a plurality of memory cells MCs disposed at intersections between the word-lines WL0~WLm-1 and the bit-lines BTL0~BTLn-1. Each of the memory cells MCs includes a cell transistor coupled to each of the word-lines WL0~WLm-1 and each of the bit-lines BTL0~BTLn-1 and a cell capacitor coupled to the cell transistor.

Each of the word-lines WL0~WLm-1 extends in a first direction DR1 and each of the bit-lines BTL1~BTLn-1 extends in a second direction DR2 perpendicular to the first direction DR1.

In addition, the memory cells MCs may have different arrangement depending on that the memory cells MCs are coupled to an even word-line (for example, WL0) or an odd word-line (for example, WL1). That is, a bit-line coupled to adjacent memory cells may be different depending on whether a word-line selected by an access address is an even word-line or an odd word-line. Each of the memory cells MCs includes an access (cell) transistor coupled to one of the word-lines WL0~WLm-1 and one of the bit-lines BTL0~BTLn-1 and a storage (cell) capacitor coupled to the cell transistor. That is, each of the memory cells MCs has a DRAM cell structure.

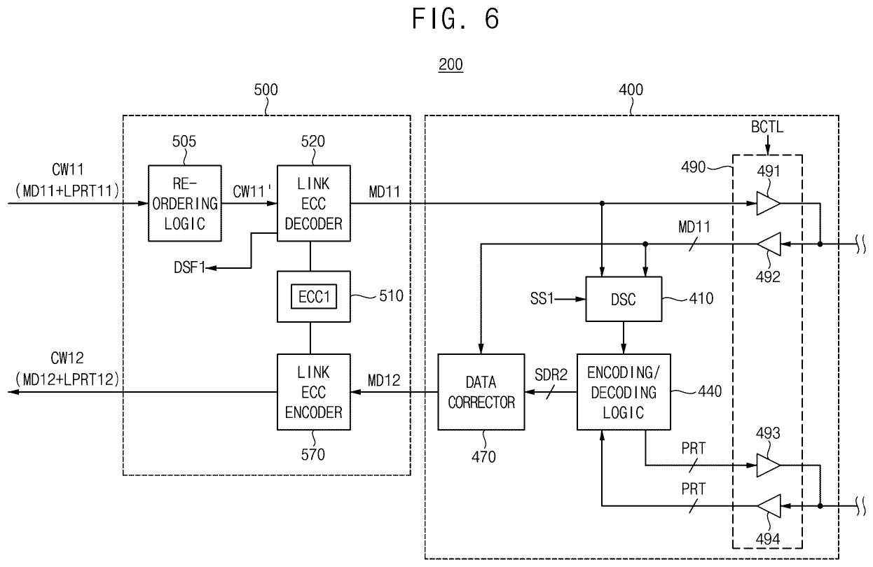

FIG. 6 illustrates a portion of the semiconductor memory device of FIG. 4.

In FIG. 6, the link ECC engine 500 and the on-die ECC engine 400 of the semiconductor memory device 200 are illustrated.

Referring to FIG. 6, the link ECC engine 500 may include re-ordering logic 505, a link ECC decoder 520, a link ECC encoder 570 and first memory 510. The first memory 510 may store a first ECC ECC1.

The on-die ECC engine 400 may include a data selection circuit DSC 410, an encoding/decoding logic 440, a data corrector 470 and a buffer circuit 490.

The buffer circuit 490 may include a plurality of buffers 491, 492, 493 and 494. The plurality of buffers 491, 492, 493 and 494 may be controlled based on a buffer control signal BCTL.

The re-ordering logic 505, in the write operation, may receive the first codeword CW11 including the first main data MID11 and the first link parity data LPRT11, may generate a first intermediate codeword CW11′ by re-ordering data bits of the first main data MD11 and link parity bits of the first link parity data LPRT11, and may provide the first intermediate codeword CW11′ to the link ECC decoder 520.

The link ECC decoder 520 may receive the first intermediate codeword CW11′, may generate a first syndrome including a plurality of syndrome bits based on the first intermediate codeword CW11′ and the first parity check matrix that is based on the first ECC ECC1, may generate the decoding status flag DSF1 indicating whether the transmission error is detected in the first codeword CW11 using a characteristic of the first syndrome based on the regularity of the first parity check matrix while decoding the first syndrome, may correct the error bit of the first intermediate codeword CW11′ (e.g., the first codeword CW11) based on the decoded first syndrome, may provide the main data MD11 of the first codeword CW11, which is corrected, to the on-die ECC engine 400, and may transmit the decoding status flag DSF1 to the memory controller 100.

The link ECC decoder 520 may divide the plurality of syndrome bits into a plurality of sets, may generate counted values by counting a number of syndrome bits having a logic high levels in each of the plurality of sets and may generate the decoding status flag DSF1 based on the counted values.

The buffer 491, in the write operation, may receive the first main data MD11 from the link ECC decoder 520 and may provide the first main data MD11 to the memory cell array 310. The buffer 492, in the read operation, may receive the first main data MD11 from the memory cell array 310 and may provide the first main data MD11 to the data selection circuit 410 and the data corrector 470.

The data selection circuit 410, based on a selection signal SS1, may provide the first main data MD11 from the link ECC decoder 520 to the encoding/decoding logic 440 in the write operation and may provide the first main data MD11 to the encoding/decoding logic 440 from the buffer 492 in the read operation.

The encoding/decoding logic 440, in the write operation, may receive the first main data MD11 from the link ECC decoder 520, may generate a parity data PRT by performing on an ECC encoding on the first main data MD11 and may provide the parity data PRT to the memory cell array 310 through the buffer 493. The encoding/decoding logic 440, in the read operation, may receive the first main data MD11 from the data selection circuit 410, may receive the parity data PRT from the buffer 494, may generate a second syndrome SDR2 by performing on a second ECC decoding on the first main data MD11 based on the parity data PRT and may provide the second syndrome SDR2 to the data corrector 470.

The data corrector 470, in the read operation, may receive the first main data MD11, may generate a second main data MD12 by correcting an error bit in the first main data MD11 based on the second syndrome SDR2 and may provide the second main data MD12 to the link ECC encoder 570.

The link ECC encoder 570, in the read operation, may generate a second link parity data LPRT12 by performing an ECC encoding on the second main data MD12 based on the first ECC ECC1 and may transmit the second codeword CW12 including the second main data MID12 and the second link parity data LPRT12 to the memory controller 100.

In FIG. 6, the first selection signal SS1 may be included in the third control signal CTL3 in FIG. 4 and the buffer control signal BCTL may be included in the second control signal CTL2 in FIG. 4.

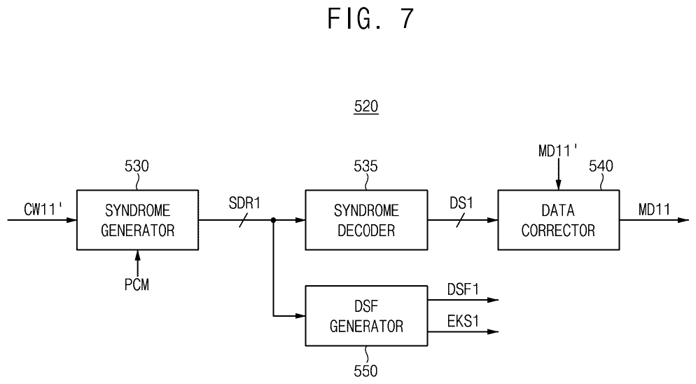

FIG. 7 is a block diagram illustrating an example of the link ECC decoder in the link ECC engine in FIG. 6 according to example embodiments.

Referring to FIG. 7, the link ECC decoder 520 may include a syndrome generator 530, a syndrome decoder 535, a data corrector 540 and a decoding status flag (DSF) generator 550.

The syndrome generator 530 may generate a first syndrome SDR1 based on a first parity check matrix PCM and the first intermediate codeword CW11′ which is obtained by re-arranging the data bits and link parity bits of the first codeword CW11. The syndrome generator 530 may generate the first syndrome SDR1 by performing a matrix-multiplication operation on the first intermediate codeword CW11′ and the first parity check matrix PCM.

The syndrome decoder 535 may generate a decoding signal DS1 indicating a position of an error in the first main data MD11 by decoding the first syndrome SDR1 and may provide the decoding signal DS1 to the data corrector 540.

The data corrector 540 may generate the corrected first main data MD11 by correcting an error bit of a main data MD11′ in the first intermediate codeword CW11′ based on the decoding signal DS1. The data corrector 540 may provide the corrected first main data MD11 to on-die ECC engine 400.

The DSF generator 550 may generate the decoding status flag DSF1 and the error kind signal EKS1 based on the first syndrome SDR1 in parallel with an operation of the syndrome decoder 535 (e.g., in parallel with the syndrome decoder 535 generating the decoding signal DS1), may transmit the decoding status flag DSF1 to the memory controller 100 and may provide the error kind signal EKS1 to the control logic circuit 210. The DSF generator 550 may divide the plurality of syndrome bits of the first syndrome SDR1 into a plurality of sets, may generate counted values by counting a number of syndrome bits having a logic high levels in each of the plurality of set and may generate the decoding status flag DSF1 based on the counted values.

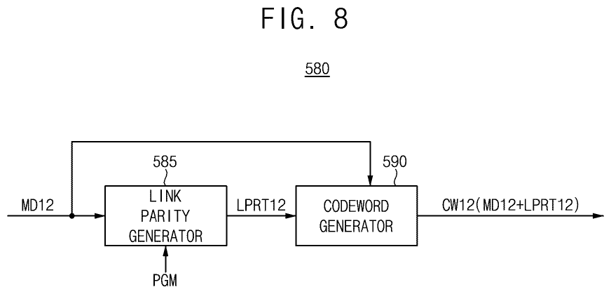

FIG. 8 is a block diagram illustrating an example of the link ECC encoder in the link ECC engine in FIG. 6 according to example embodiments.

Referring to FIG. 8, the link ECC encoder 580 may include a link parity generator 585 and a codeword generator 590.

The link parity generator 585 may receive the second main data MD12 from the on-die ECC engine 400 in FIG. 6, may generate the second link parity data LPRT12 based on the second main data MD12 and a parity generation matrix PGM that is based on the first ECC ECC1 and may provide second link parity data LPRT12 to the codeword generator 590. The link parity generator 585 may generate second link parity data LPRT12 by performing a matrix-multiplication on the second main data MD12 and the parity generation matrix PGM.

The codeword generator 590 may receive the second main data MD12 and the second link parity data LPRT12, may generate the second codeword CW12 including the second main data MD12 and the second link parity data LPRT12 and may transmit the second codeword CW12 to the memory controller 100.

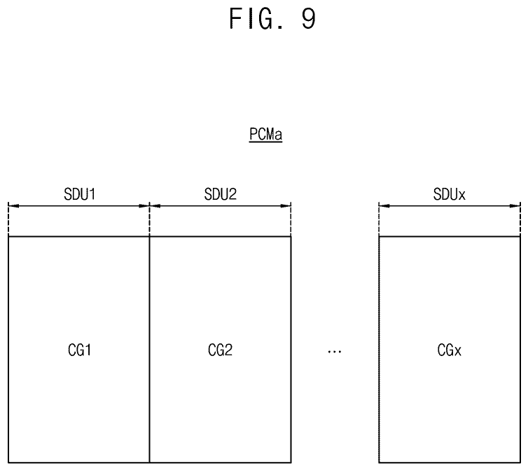

FIG. 9 illustrates an example of a parity check matrix used in the link ECC engine in FIG. 6 according to some example embodiments.

In FIG. 9, it is assumed that the first intermediate codeword CW11′ includes a plurality of sub data units SDU1, SDU2, ..., SDUx, and x is a natural number equal to or greater than twelve.

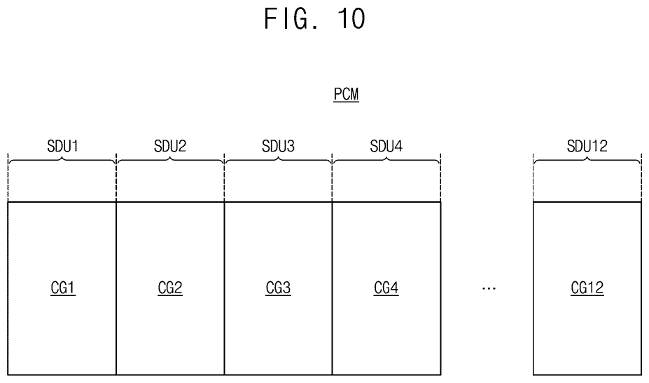

Referring to FIG. 9, a parity check matrix PCMa that is based on the first ECC ECC1 may be divided into a plurality of code groups CG1, CG2, ..., CGx corresponding to the plurality of sub data units SDU1, SDU2, ..., SDUx FIG. 10 illustrates an example of the parity check matrix in FIG. 9 according to some example embodiments.

Referring to FIG. 10, the data bits and the link parity bits of the first intermediate codeword CW11′ may be divided into a plurality of sub data units SDU1, SDU2, SDU3, SDU4, ..., SDU12 and the parity check matrix PCM may include a plurality of code groups CG1, CG2, CG3, CG4, ..., CG12 corresponding to the plurality of sub data units SDU1, SDU2, SDU3, SDU4, ..., SDU12.

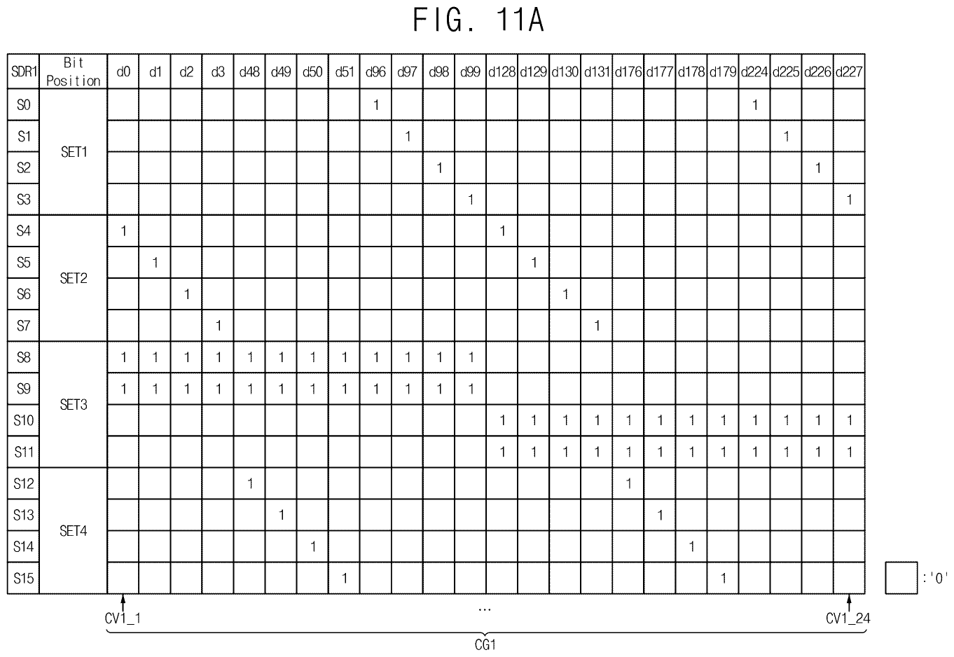

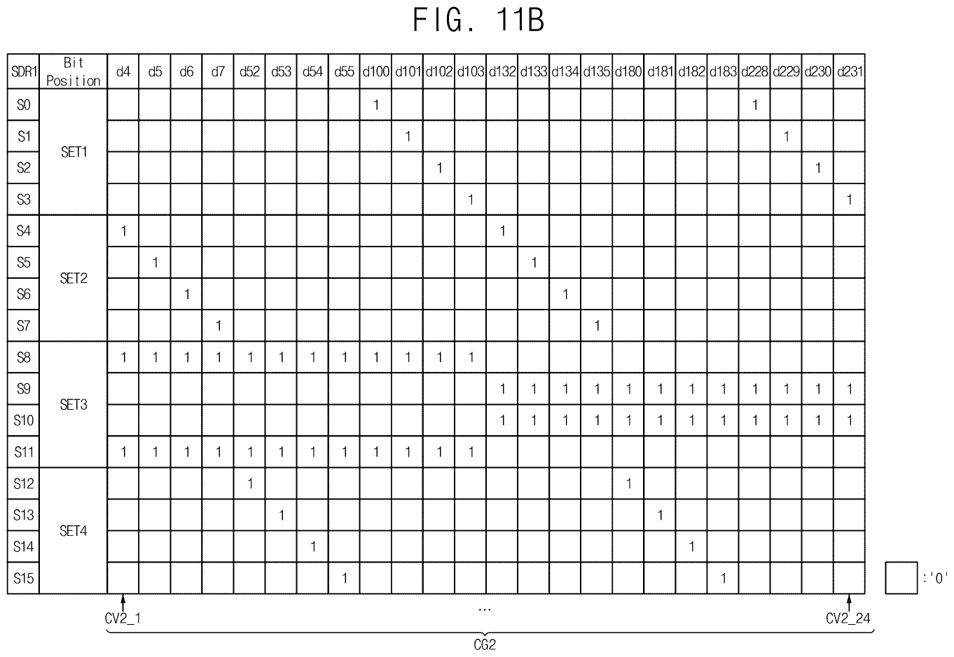

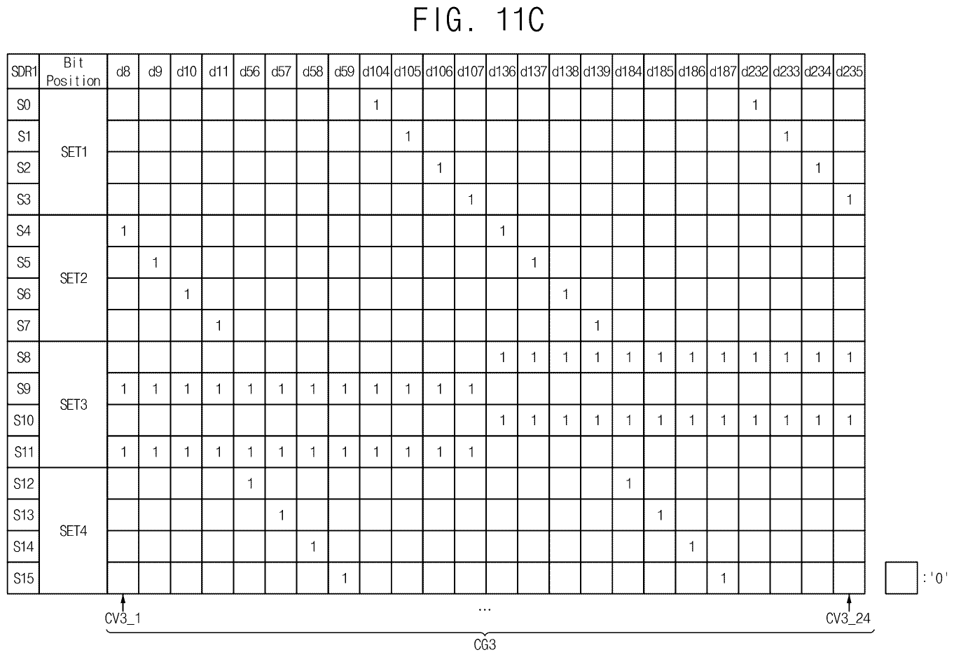

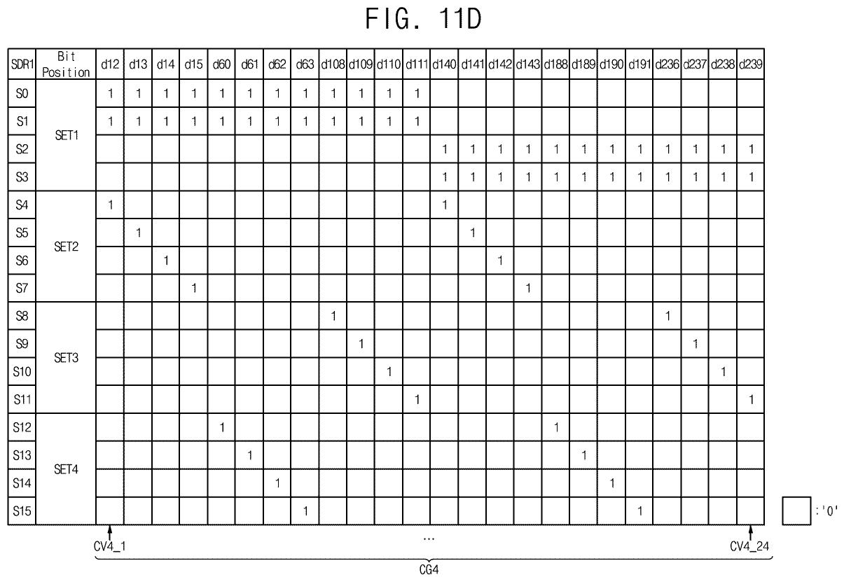

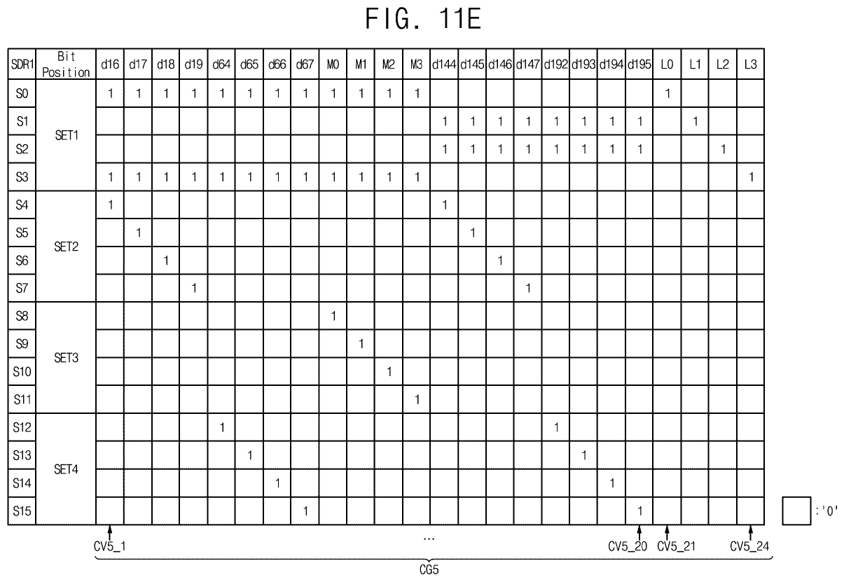

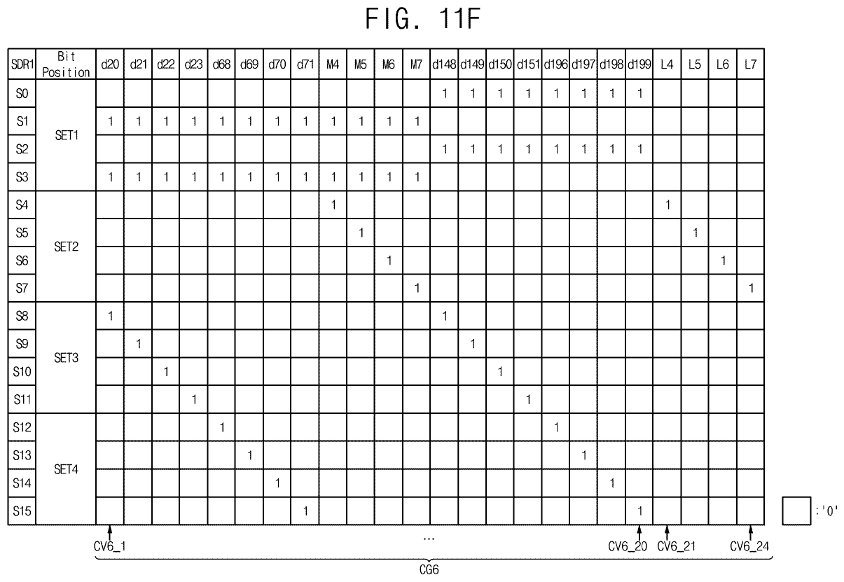

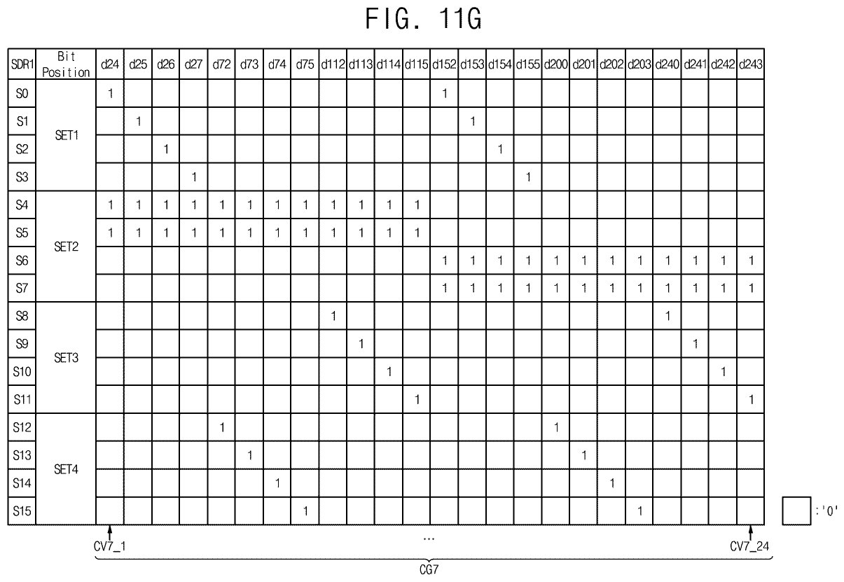

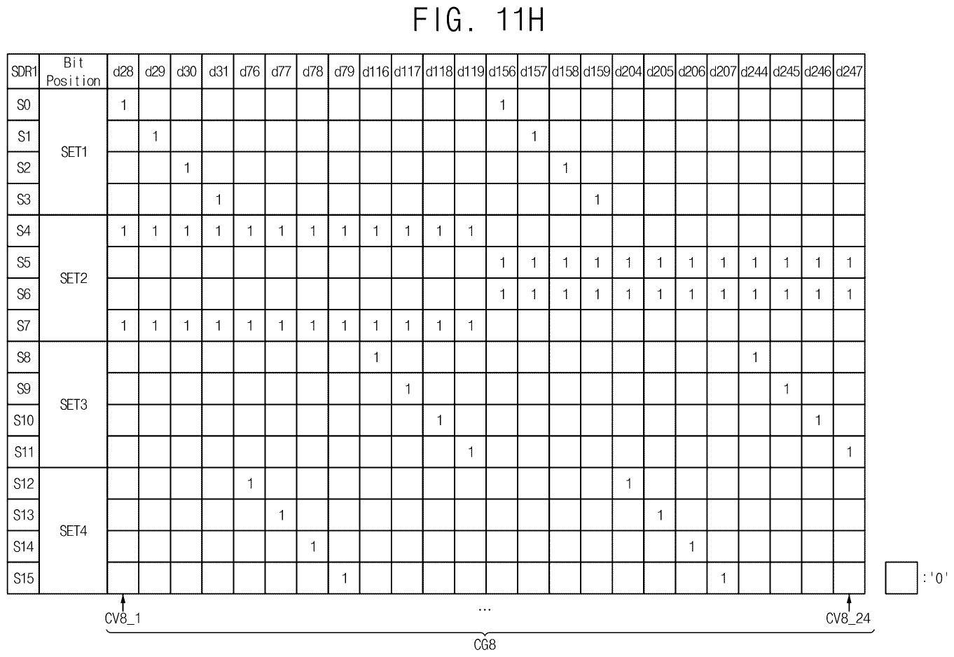

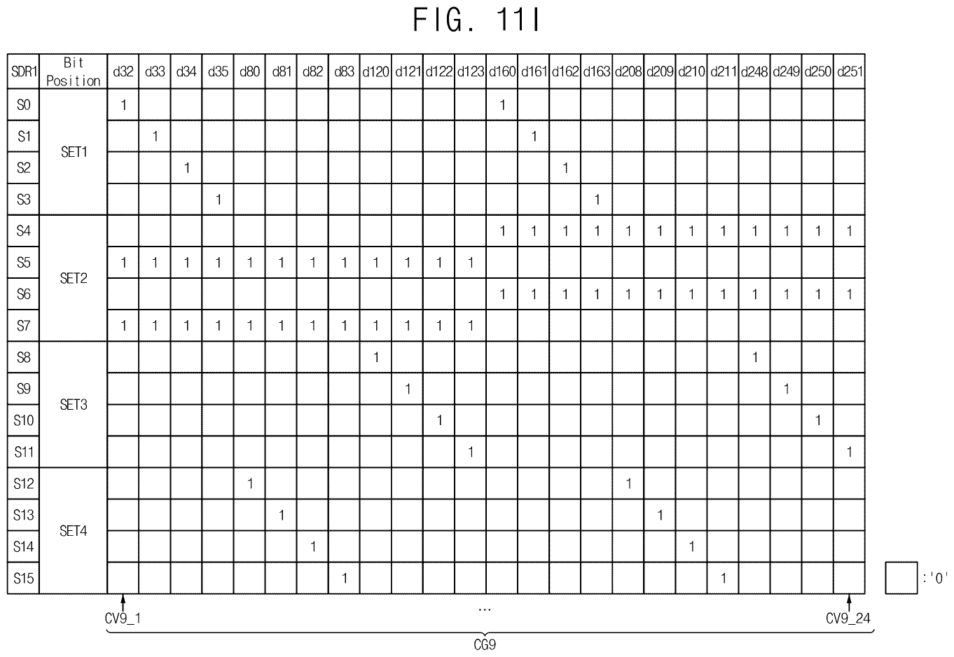

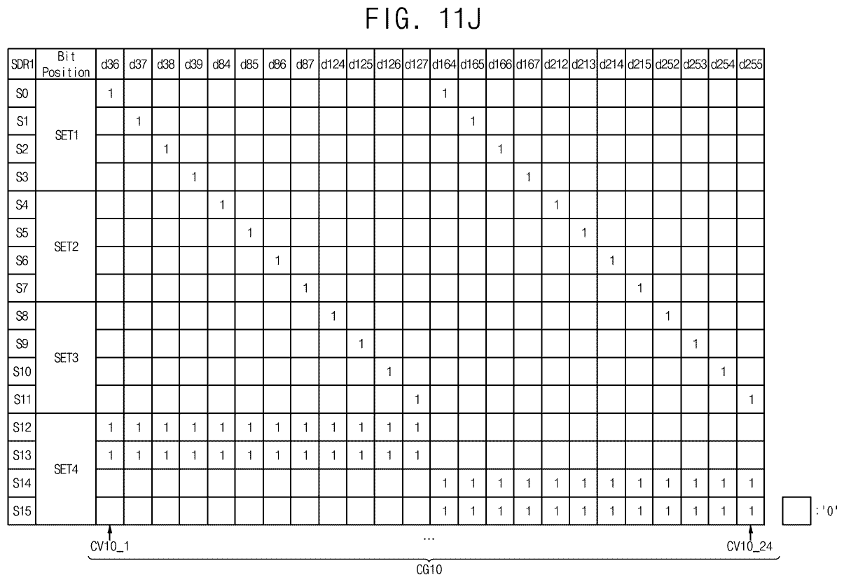

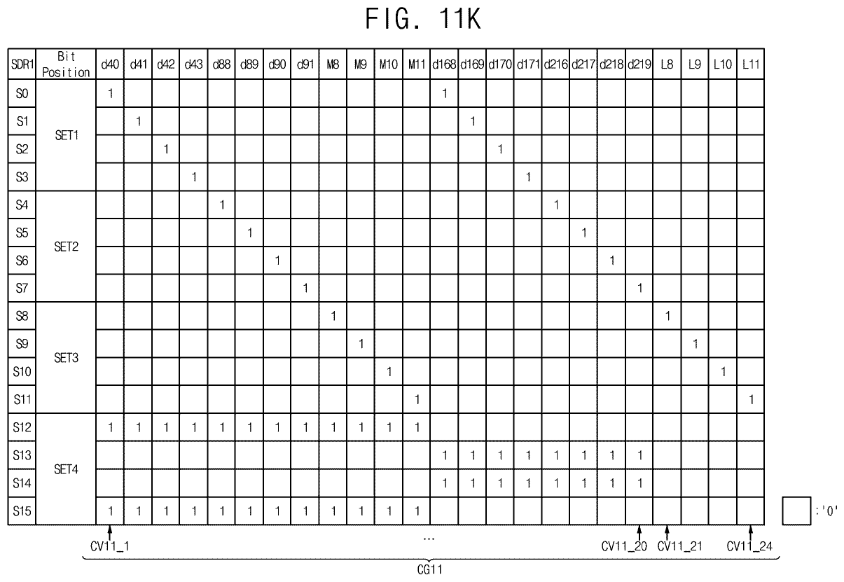

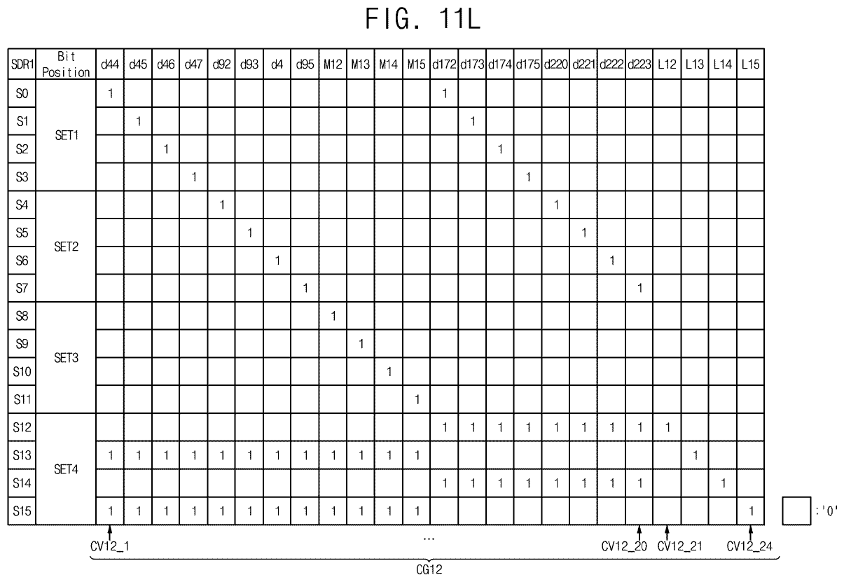

FIGS. 11A through 11L illustrate an example of a plurality of code groups of the parity check matrix of FIG. 10 according to example embodiments.

In FIGS. 11A through 11L, assuming that the first main data MD11 of the first intermediate codeword CW11′ includes data bits d0~d255 of 256-bit and data bits M0~M15 Of 16-bit and the first link parity data LPRT11 includes L0~L15. In FIGS. 11A through 11L, syndrome bits S0, S1, S2, S3, S4, S5, S6, S7, S8, S9, S10, S11, S12, S13, S14 and S15 of the first syndrome SDR1 are altogether illustrated for convenience of explanation. The syndrome bits S0, S1, S2, S3, S4, S5, S6, S7, S8, S9, S10, S11, S12, S13, S14 and S15 may be divided into a plurality of sets SET1, SET2, SET3 and SET4, and each of the plurality of sets SET1, SET2, SET3 and SET4 may include four syndrome bits. The set SET1 may include the syndrome bits S0, S1, S2 and S3, the set SET2 may include the syndrome bits S4, S5, S6 and S7, the set SET3 may include the syndrome bits S8, S9, S10 and S11 and the set SET4 may include the syndrome bits S12, S13, S14 and S15.

Referring to FIG. 11A, a code group CG1 of the parity check matrix PCM may include a plurality of column vectors CV1_1~CV1_24 corresponding to data bits d0, d1, d2, d3, d48, d49, d50, d51, d96, d97, d98, d99, d128, d129, d130, d131, d176, d177, d178, d179, d224, d225, d226 and d227. Each of the plurality of column vectors CV1_1~CV1_24 may include three elements having a logic high level. In FIG. 11A, each empty rectangular may indicate a logic low level (e.g., ‘0’).

When the first syndrome SDR1 matches one of the plurality of column vectors CV1_1~CV1_24 of the code group CG1, among the plurality of sets SET1, SET2, SET3 and SET4, a number of at least one set including two syndrome bits (e.g., two elements) having a logic high level may be one, a number of at least one set including one syndrome bit (e.g., an element) having a logic high level may be one, and a number of at least one set including four syndrome bits (e.g., four elements) having a logic low level (e.g., a number of at least one set including zero syndrome bits having a logic high level) may be two.

Referring to FIG. 11B, a code group CG2 of the parity check matrix PCM may include a plurality of column vectors CV2_1~CV2_24 corresponding to data bits d4, d5, d6, d7, d52, d53, d54, d55, d100, d101, d102, d103, d132, d133, d134, d135, d180, d181, d182, d183, d228, d229, d230 and d231. Each of the plurality of column vectors CV2_1~CV2_24 may include three elements having a logic high level. In FIG. 11B, each empty rectangular may indicate a logic low level (e.g., ‘0’).

When the first syndrome SDR1 matches one of the plurality of column vectors CV2 1~CV2_24 of the code group CG2, among the plurality of sets SET1, SET2, SET3 and SET4, a number of at least one set including two syndrome bits having a logic high level may be one, a number of at least one set including one syndrome bit having a logic high level may be one, and a number of at least one set including four syndrome bits having a logic low level (e.g., a number of at least one set including zero syndrome bits having a logic high level) may be two.

Referring to FIG. 11C, a code group CG3 of the parity check matrix PCM may include a plurality of column vectors CV3_1~CV3_24 corresponding to data bits d8, d9, d10, d11, d56, d57, d58, d59, d104, d105, d106, d107, d136, d137, d138, d139, d184, d185, d186, d187, d232, d233, d234 and d235. Each of the plurality of column vectors CV3_1~CV3_24 may include three elements having a logic high level. In FIG. 11C, each empty rectangular may indicate a logic low level (e.g., ‘0’).

When the first syndrome SDR1 matches one of the plurality of column vectors CV3 1~CV3_24 of the code group CG3, among the plurality of sets SET1, SET2, SET3 and SET4, a number of at least one set including two syndrome bits having a logic high level may be one, a number of at least one set including one syndrome bit having a logic high level may be one, and a number of at least one set including four syndrome bits having a logic low level (e.g., a number of at least one set including zero syndrome bits having a logic high level) may be two.

Referring to FIG. 11D, a code group CG4 of the parity check matrix PCM may include a plurality of column vectors CV4_1~CV4_24 corresponding to data bits d12, d13, d14, d15, d60, d61, d62, d63, d108, d109, d110, d111, d140, d141, d142, d143, d188, d189, d190, d191, d236, d237, d238 and d239. Each of the plurality of column vectors CV4_1~CV4_24 may include three elements having a logic high level. In FIG. 11D, each empty rectangular may indicate a logic low level (e.g., ‘0’).

When the first syndrome SDR1 matches one of the plurality of column vectors CV4 1~CV4_24 of the code group CG4, among the plurality of sets SET1, SET2, SET3 and SET4, a number of at least one set including two syndrome bits having a logic high level may be one, a number of at least one set including one syndrome bit having a logic high level may be one, and a number of at least one set including four syndrome bits having a logic low level (e.g., a number of at least one set including zero syndrome bits having a logic high level) may be two.

Referring to FIG. 11E, a code group CG5 of the parity check matrix PCM may include a plurality of column vectors CV5_1~CV5_20 corresponding to data bits d16, d17, d18, d19, d64, d65, d66, d67, MO, M1, M2, M3, d144, d145, d146, d147, d192, d193, d194 and d195 and a plurality of column vectors CV5_21~CV5_24 corresponding to link parity bits L0, L1, L2 and L3. Each of the plurality of column vectors CV5_1~CV5_20 may include three elements having a logic high level and each of the plurality of column vectors CV5_21~CV5_24 may include one element having a logic high level. In FIG. 11E, each empty rectangular may indicate a logic low level (e.g., ‘0’).

When the first syndrome SDR1 matches one of the plurality of column vectors CV5_1~CV5_20 of the code group CG5, among the plurality of sets SET1, SET2, SET3 and SET4, a number of at least one set including two syndrome bits having a logic high level may be one, a number of at least one set including one syndrome bit having a logic high level may be one, and a number of at least one set including four syndrome bits having a logic low level (e.g., a number of at least one set including zero syndrome bits having a logic high level) may be two. When the first syndrome SDR1 matches one of the plurality of column vectors CV5 21~CV5 24 of the code group CG5, among the plurality of sets SET1, SET2, SET3 and SET4, a number of at least one set including two syndrome bits having a logic high level may be one, and a number of at least one set including four syndrome bits having a logic low level (e.g., a number of at least one set including zero syndrome bits having a logic high level) may be three.

Referring to FIG. 11F, a code group CG6 of the parity check matrix PCM may include a plurality of column vectors CV6_1~CV6_20 corresponding to data bits d20, d21, d22, d23, d68, d69, d70, d71, M4, M5, M6, M7, d148, d149, d150, d151, d196, d197, d198 and d199 and a plurality of column vectors CV6_21~CV6_24 corresponding to link parity bits L4, L5, L6 and L7. Each of the plurality of column vectors CV6_1~CV6_20 may include three elements having a logic high level and each of the plurality of column vectors CV6_21~CV6_24 may include one element having a logic high level. In FIG. 11F, each empty rectangular may indicate a logic low level (e.g., ‘0’).

When the first syndrome SDR1 matches one of the plurality of column vectors CV6_1~CV6_20 of the code group CG6, among the plurality of sets SET1, SET2, SET3 and SET4, a number of at least one set including two syndrome bits having a logic high level may be one, a number of at least one set including one syndrome bit having a logic high level may be one, and a number of at least one set including four syndrome bits having a logic low level (e.g., a number of at least one set including zero syndrome bits having a logic high level) may be two. When the first syndrome SDR1 matches one of the plurality of column vectors CV6_21~CV6_24 of the code group CG6, among the plurality of sets SET1, SET2, SET3 and SET4, a number of at least one set including two syndrome bits having a logic high level may be one, and a number of at least one set including four syndrome bits having a logic low level (e.g., a number of at least one set including zero syndrome bits having a logic high level) may be three.

Referring to FIG. 11G, a code group CG7 of the parity check matrix PCM may include a plurality of column vectors CV7_1~CV7_24 corresponding to data bits, d24, d25, d26, d27, d72, d73, d74, d75, d112, d113, d114, d115, d152, d153, d154, d155, d200, d201, d202, d203, d240, d241, d242 and d243. Each of the plurality of column vectors CV7_1~CV7_24 may include three elements having a logic high level. In FIG. 11G, each empty rectangular may indicate a logic low level (e.g., ‘0’).

When the first syndrome SDR1 matches one of the plurality of column vectors CV7 1~CV7_24 of the code group CG7, among the plurality of sets SET1, SET2, SET3 and SET4, a number of at least one set including two syndrome bits (e.g., two elements) having a logic high level may be one, a number of at least one set including one syndrome bit (e.g., an element) having a logic high level may be one, and a number of at least one set including four syndrome bits (e.g., four elements) having a logic low level (e.g., a number of at least one set including zero syndrome bits having a logic high level) may be two.

Referring to FIG. 11H, a code group CG8 of the parity check matrix PCM may include a plurality of column vectors CV8_1~CV8_24 corresponding to data bits d28, d29, d30, d31, d76, d77, d78, d79, d116, d117, d118, d119, d156, d157, d158, d159, d204, d205, d206, d207, d244, d245, d246 and d247. Each of the plurality of column vectors CV8_1~CV8_24 may include three elements having a logic high level. In FIG. 11H, each empty rectangular may indicate a logic low level (e.g., ‘0’).

When the first syndrome SDR1 matches one of the plurality of column vectors CV8_1~CV8_24 of the code group CG8, among the plurality of sets SET1, SET2, SET3 and SET4, a number of at least one set including two syndrome bits (e.g., two elements) having a logic high level may be one, a number of at least one set including one syndrome bit (e.g., an element) having a logic high level may be one, and a number of at least one set including four syndrome bits (e.g., four elements) having a logic low level (e.g., a number of at least one set including zero syndrome bits having a logic high level) may be two.

Referring to FIG. 11I, a code group CG9 of the parity check matrix PCM may include a plurality of column vectors CV9_1~CV9_24 corresponding to data bits d32, d33, d34, d35, d80, d81, d82, d83, d120, d121, d122, d123, d160, d161, d162, d163, d208, d209, d210, d211, d248, d249, d250 and d251. Each of the plurality of column vectors CV9_1~CV9_24 may include three elements having a logic high level. In FIG. 11I, each empty rectangular may indicate a logic low level (e.g., ‘0’).

When the first syndrome SDR1 matches one of the plurality of column vectors CV9 1~CV9_24 of the code group CG9, among the plurality of sets SET1, SET2, SET3 and SET4, a number of at least one set including two syndrome bits (e.g., two elements) having a logic high level may be one, a number of at least one set including one syndrome bit (e.g., an element) having a logic high level may be one, and a number of at least one set including four syndrome bits (e.g., four elements) having a logic low level (e.g., a number of at least one set including zero syndrome bits having a logic high level) may be two.

Referring to FIG. 11J, a code group CG10 of the parity check matrix PCM may include a plurality of column vectors CV10_1~CV10_24 corresponding to data bits d36, d37, d38, d39, d84, d85, d86, d87, d124, d125, d126, d127, d164, d165, d166, d167, d212, d213, d214, d215, d252, d253, d254 and d255. Each of the plurality of column vectors CV10_1~CV10_24 may include three elements having a logic high level. In FIG. 11J, each empty rectangular may indicate a logic low level (e.g., ‘0’).

When the first syndrome SDR1 matches one of the plurality of column vectors CV10_1~CV10_24 of the code group CG10, among the plurality of sets SET1, SET2, SET3 and SET4, a number of at least one set including two syndrome bits (e.g., two elements) having a logic high level may be one, a number of at least one set including one syndrome bit (e.g., an element) having a logic high level may be one, and a number of at least one set including four syndrome bits (e.g., four elements) having a logic low level (e.g., a number of at least one set including zero syndrome bits having a logic high level) may be two.

Referring to FIG. 11K, a code group CG11 of the parity check matrix PCM may include a plurality of column vectors CV11_1~CV11_20 corresponding to data bits d40, d41, d42, d43, d88, d89, d90, d91, M8, M9, M10, M11, d168, d169, d170, d171, d216, d217, d218 and d219 and a plurality of column vectors CV11_21~CV11_24 corresponding to link parity bits L8, L9, L10 and L11. Each of the plurality of column vectors CV11_1~CV11_20 may include three elements having a logic high level and each of the plurality of column vectors CV11_21~CV11_24 may include one element having a logic high level. In FIG. 11K, each empty rectangular may indicate a logic low level (e.g., ‘0’).

When the first syndrome SDR1 matches one of the plurality of column vectors CV11_1~CV11_20 of the code group CG11, among the plurality of sets SET1, SET2, SET3 and SET4, a number of at least one set including two syndrome bits having a logic high level may be one, a number of at least one set including one syndrome bit having a logic high level may be one, and a number of at least one set including four syndrome bits having a logic low level (e.g., a number of at least one set including zero syndrome bits having a logic high level) may be two. When the first syndrome SDR1 matches one of the plurality of column vectors CV11_21~CV11_24 of the code group CG11, among the plurality of sets SET1, SET2, SET3 and SET4, a number of at least one set including two syndrome bits having a logic high level may be one, and a number of at least one set including four syndrome bits having a logic low level (e.g., a number of at least one set including zero syndrome bits having a logic high level) may be three.

Referring to FIG. 11L, a code group CG12 of the parity check matrix PCM may include a plurality of column vectors CV12_1~CV12_20 corresponding to data bits d44, d45, d46, d47, d92, d93, d94, d95, M12, M13, M14, M15, d172, d173, d174, d175, d220, d221, d222 and d223 and a plurality of column vectors CV12_21~CV12_24 corresponding to link parity bits L12, L13, L14 and L15. Each of the plurality of column vectors CV12_1~CV12_20 may include three elements having a logic high level and each of the plurality of column vectors CV12_21~CV12_24 may include one element having a logic high level. In FIG. 11L, each empty rectangular may indicate a logic low level (e.g., ‘0’).

When the first syndrome SDR1 matches one of the plurality of column vectors CV12_1~CV12_20 of the code group CG12, among the plurality of sets SET1, SET2, SET3 and SET4, a number of at least one set including two syndrome bits having a logic high level may be one, a number of at least one set including one syndrome bit having a logic high level may be one, and a number of at least one set including four syndrome bits having a logic low level (e.g., a number of at least one set including zero syndrome bits having a logic high level) may be two. When the first syndrome SDR1 matches one of the plurality of column vectors CV12_21~CV12_24 of the code group CG12, among the plurality of sets SET1, SET2, SET3 and SET4, a number of at least one set including two syndrome bits having a logic high level may be one, and a number of at least one set including four syndrome bits having a logic low level (e.g., a number of at least one set including zero syndrome bits having a logic high level) may be three.

In FIGS. 11A through 11L, the column vectors corresponding to the data bits d0~d255 and M0~M15 may be referred to as a first part of column vectors and the column vectors corresponding to the link parity bits L0~L15 may be referred to as a second part of column vectors. A number of elements having a logic high level in each of the first part of column vectors may correspond to a first value (for example, three) and a number of elements having a logic high level in each of the second part of column vectors may correspond to a second value (for example, one) smaller than the first value.

When a correctable error bit occurs in the first main data MD11, the first syndrome SDR1 may match one of the first part of column vectors. When an error bit occurs in the first link parity data LPRT11, the first syndrome SDR1 may match one of the second part of column vectors. When uncorrectable error bits occur in the first codeword CW11, at least one of the syndrome bits of the first syndrome SDR1 is not a logic low level and the first syndrome SDR1 matches none of the column vectors of the parity check matrix PCM.

As explained with reference to FIGS. 11A through 11L, because arrangements of the column vectors of the parity check matrix PCM have a regularity, the DSF generator 550 in the link ECC decoder 520 may determine a type of the transmission error and may determine whether the transmission error occurs based on a first number, a second number and a third number. The first number may designate a number of at least one set including two syndrome bits having a logic high level, among the first set, the second set, the third set and the fourth set. The second number may designate a number of at least one set including one syndrome bit having a logic high level, among the first set, the second set, the third set and the fourth set. The third number may designate a number of at least one set including four syndrome bits having a logic low level, among the first set, the second set, the third set and the fourth set.

For example, the DSF generator 550 in the link ECC decoder 520, in response to the third number being four, may determine that the transmission error does not occur.

For example, the DSF generator 550 in the link ECC decoder 520, in response to the third number being three, the second number being one and the first number being zero, may determine that the transmission error occurs in the first link parity data LPRT11.

For example, the DSF generator 550 in the link ECC decoder 520, in response to the third number being two, the second number being one and the first number being one, may determine that the transmission error, which is correctable, occurs in the first main data MD11.

For example, the DSF generator 550 in the link ECC decoder 520, in response to at least one of the plurality of syndrome bits S0, S1, S2, S3, S4, S5, S6, S7, S8, S9, S10, S11, S12, S13, S14 and S15 having a logic high level and the first syndrome SDR1 not matching respective one of the plurality of column vectors of the parity check matrix PCM, may determine that the transmission error, which is uncorrectable, occurs in the first codeword CW11 and may output the decoding status flag DSF1 with a logic high level.

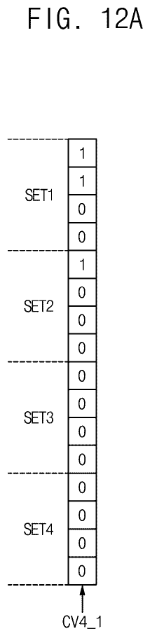

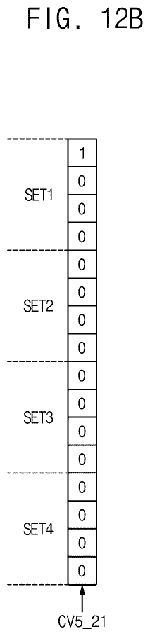

FIG. 12A illustrates one of the column vectors in FIGS. 11A through 11L.

Referring to FIG. 12A, when the first syndrome SDR1 matches the column vector CV4_1, among the first set SET1, the second set SET2, the third set SET3 and the fourth set SET4, because the first number designating a number of at least one set (for example, the set SET1) including two syndrome bits having a logic high level is one, the second number designating a number of at least one set (for example, the set SET2) including one syndrome bit having a logic high level is one and the third number designating a number of at least one set (for example, the set SET3 and the set SET4) including four syndrome bits having a logic low level is two, the DSF generator 550 in the link ECC decoder 520 may determine that the transmission error, which is correctable, occurs in the first main data MD11.

FIG. 12B illustrates one of the column vectors in FIGS. 11A through 11L.

Referring to FIG. 12B, when the first syndrome SDR1 matches the column vector CV5_21, among the first set SET1, the second set SET2, the third set SET3 and the fourth set SET4, because the first number designating a number of at least one set including two syndrome bits having a logic high level is zer0, the second number designating a number of at least one set (for example, the set SET1) including one syndrome bit having a logic high level is one and the third number designating a number of at least one set (for example, the set SET2, the set SET3 and the set SET4) including four syndrome bits having a logic low level is three, the DSF generator 550 in the link ECC decoder 520 may determine that the transmission error occurs in the first link parity data LPRT11.

As mentioned above, in parallel with an operation of the syndrome decoder 535, the DSF generator 550 may divide the syndrome bits S0, S1, S2, S3, S4, S5, S6, S7, S8, S9, S10, S11, S12, S13, S14 and S15 of the first syndrome SDR1 into the plurality of sets SET1, SET2, SET3 and SET4, may generate counted values by counting a number of syndrome bits having a logic high levels in each of the plurality of sets SET1, SET2, SET3 and SET4 and may generate the decoding status flag DSF1 based on the counted values. Because when the DSF generator 550 generates the decoding status flag DSF1, the DSF generator 550 does not use a result of the syndrome decoding, the link ECC decoder 520 may reduce the decoding latency and may reduced occupied circuit area associated with the link ECC decoder 520.

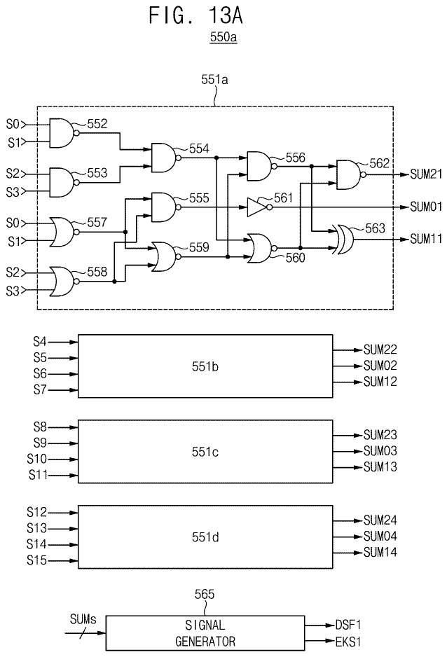

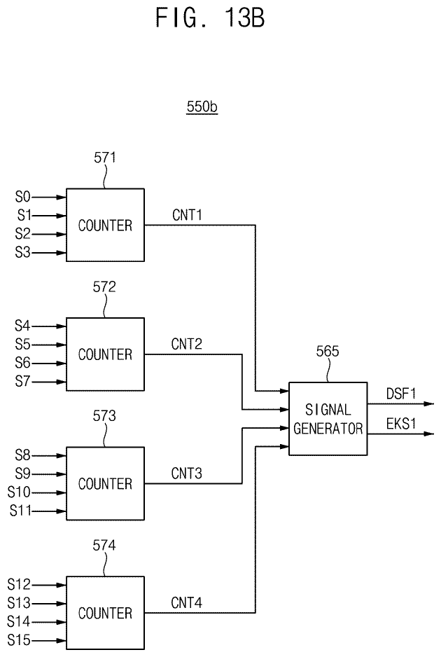

FIG. 13A is a block diagram illustrating an example of the DSF generator in FIG. 7 according to example embodiments.

Referring to FIG. 13A, a DSF generator 550a may include a plurality of summed signal generators 551a, 551b, 551c, 551d and a signal generator 565.

The summed signal generator 551a, based on the syndrome bits S0, S1, S2 and S3 of the set SET1, may generate a summed signal SUM21 indicting that the set SET1 includes two elements having a logic high level, may generate a summed signal SUM01 indicting that the set SET1 includes zero element having a logic high level, and may generate a summed signal SUM11 indicting that the set SET1 includes one element having a logic high level.

The summed signal generator 551a may include a plurality of NAND gates 552, 553, 554, 555, 556 and 562, a plurality of NOR gates 557, 558, 559 and 560, an inverter 561 and an exclusive OR gate 563.

The NAND gate 552 may perform a NAND operation on the syndrome bits SO and S1. The NAND gate 553 may perform a NAND operation on the syndrome bits S2 and S3. The NOR gate 557 may perform a NOR operation on the syndrome bits S0 and S1. The NOR gate 558 may perform a NOR operation on the syndrome bits S2 and S3.

The NAND gate 554 may perform a NAND operation on outputs of the NAND gates 552 and 553. The NAND gate 555 may perform a NAND operation on outputs of the NOR gates 557 and 558. The NOR gate 559 may perform a NOR operation on the outputs of the NOR gates 557 and 558.

The NAND gate 556 may perform a NAND operation on outputs of the NAND gate 554 and the NOR gate 559. The NOR gate 560 may perform a NOR operation on the outputs of the NAND gate 554 and the NOR gate 559.

The inverter 561 may output the summed signal SUM01 by inverting the output of the NAND gate 555. The NAND gate 562 may output the summed signal SUM21 by performing a NAND operation on outputs of the NAND gate 556 and the NOR gate 560. The exclusive OR gate 563 may output the summed signal SUM11 by performing an exclusive OR operation on the outputs of the NAND gate 556 and the NOR gate 560.

The summed signal generator 551b, based on the syndrome bits S4, S5, S6 and S7 of the set SET2, may generate a summed signal SUM22 indicting that the set SET2 includes two elements having a logic high level, may generate a summed signal SUM02 indicting that the set SET2 includes zero element having a logic high level, and may generate a summed signal SUM12 indicting that the set SET2 includes one element having a logic high level.

The summed signal generator 551c, based on the syndrome bits S8, S9, S10 and S11 of the set SET3, may generate a summed signal SUM23 indicting that the set SET3 includes two elements having a logic high level, may generate a summed signal SUM03 indicting that the set SET3 includes zero element having a logic high level, and may generate a summed signal SUM13 indicting that the set SET3 includes one element having a logic high level.

The summed signal generator 551d, based on the syndrome bits S12, S13, S14 and S15 of the set SET4, may generate a summed signal SUM24 indicting that the set SET4 includes two elements having a logic high level, may generate a summed signal SUM04 indicting that the set SET4 includes zero element having a logic high level, and may generate a summed signal SUM14 indicting that the set SET4 includes one element having a logic high level.

The signal generator 565, based on a summed signal SUMs corresponding to the summed signals SUM21, SUM01, SUM11, SUM22, SUM02, SUM12, SUM23, SUM03, SUM13, SUM24, SUM04 and SUM14, may generate the decoding status flag DSF1 and the error kind signal EKS1.

Configuration of each of the summed signal generators 551b, 551c and 551d may be substantially the same as a configuration of the summed signal generator 551a.

FIG. 13B is a block diagram illustrating an example of the DSF generator in FIG. 7 according to example embodiments.

Referring to FIG. 13B, a DSF generator 550b may include a plurality of counters 571, 572, 573 and 574 and a signal generator 575.

The counter 571 may generate a counted signal CNT1 by counting syndrome bits having a logic high level among the syndrome bits S0, S1, S2 and S3 of the set SET1. The counter 572 may generate a counted signal CNT2 by counting syndrome bits having a logic high level among the syndrome bits S4, S5, S6 and S7 of the set SET2. The counter 573 may generate a counted signal CNT3 by counting syndrome bits having a logic high level among the syndrome bits S8, S9, S10 and S11 of the set SET3. The counter 574 may generate a counted signal CNT4 by counting syndrome bits having a logic high level among the syndrome bits S12, S13, S14 and S15 of the set SET4.

The signal generator 575, based on the counted signals CNT1, CNT2, CNT3 and CNT4, may generate the decoding status flag DSF1 and the error kind signal EKS1.

FIG. 14 illustrates an example of the encoding/decoding logic in the on-die ECC engine in FIG. 6 according to example embodiments.

Referring to FIG. 14, the encoding/decoding logic 440 may include a parity generator 441, a check bit generator 443, a syndrome generator 450 and a memory 445. The memory may store a second ECC (ECC2) 447.

The parity generator 441 may be connected to the memory 445 and may generate the parity data PRT based on the first main data MD11 using an array of exclusive OR gates in the write operation.

The check bit generator 443 may be connected to the memory 445 and may generate check bits CHB based on the first main data MD11 in the read operation. The syndrome generator 450 may generate the second syndrome data SDR2 based on the check bits CHB based on the first main data MD11 and the parity data PRT from the buffer 494 in the read operation. The syndrome generator 450 may generate the second syndrome SDR2 based on whether each of the check bits CHB is equal to a corresponding one of bits of the parity data PRT.

The second syndrome SDR2 may include a plurality of syndrome bits and each of the plurality of syndrome bits may indicate whether each of the check bits CHB is equal to a corresponding one of bits of the parity data PRT. Therefore, the second syndrome SDR2 may indicate a position of the error bit and a number of the error bit(s).

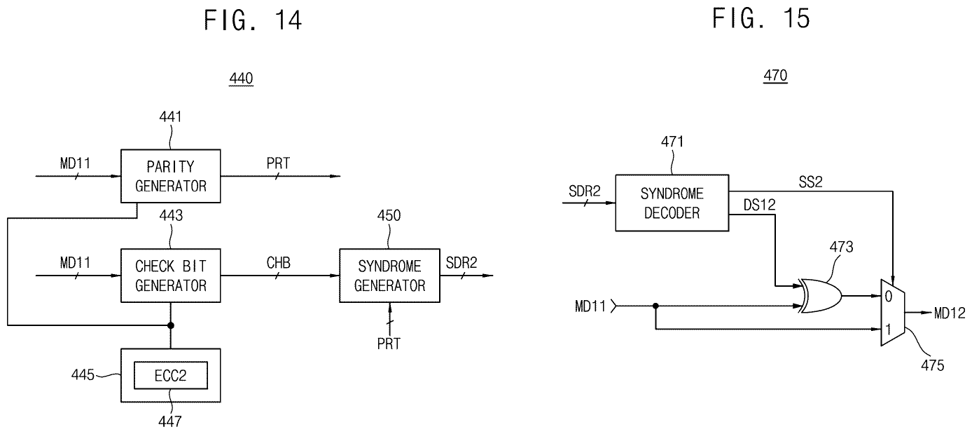

FIG. 15 illustrates an example of the data corrector in the on-die ECC engine in FIG. 6 according to example embodiments.

Referring to FIG. 15, the data corrector 470 may include a syndrome decoder 471, a bit inverter 473 and a selection circuit 475 which is implemented by a multiplexer.

The syndrome decoder 471 may decode the second syndrome SDR2 to generate a decoding signal DS12 and a selection signal SS2. The decoding signal DS12 may indicate a position of the at least one error and the selection signal SS2 may have a logic level depending on a number of the at least one error bit. The bit inverter 473 may invert the at least one error bit of the first main data MD11 in response to the decoding signal DS2. The selection circuit 475 may select one of the first main data MD11 and an output of the bit inverter 473 to provide the second main data MD12 in response to the selection signal SS2.

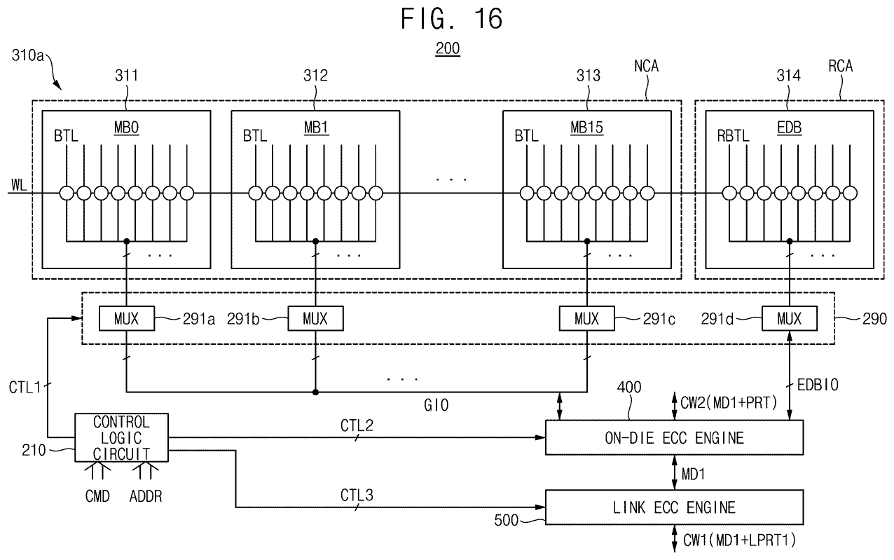

FIG. 16 illustrates a portion of the semiconductor memory device of FIG. 4 according to example embodiments.

In FIG. 16, the control logic circuit 210, the first bank array 310a, the I/O gating circuit 290, the on-die ECC engine 400 and the link ECC engine 500 are illustrated.

Referring to FIG. 16, the first bank array 310a may include a normal cell region NCA and a redundancy cell region RCA.

The normal cell region NCA may includes a plurality of first memory blocks MB0~MB15, e.g., 311, 312, ..., 313 and the redundancy cell region RCA includes at least a second memory block 314. The first memory blocks 311, 312, ..., 313 are memory blocks that determine or are used to determine a memory capacity of the semiconductor memory device 200. The second memory block 314 is for ECC and/or redundancy repair. Since the second memory block 314 for ECC and/or redundancy repair is used for ECC, data line repair and block repair to repair ‘failed’ cells generated in the first memory blocks 311~313, the second memory block 314 is also referred to as an EDB block. Each of the first memory blocks 311, 312, ..., 313 includes memory cells coupled to a word-line WL and bit-lines BTL and the second memory block 314 includes memory cells coupled to word-line WL and redundancy bit-lines RBTL. The redundancy cell region RCA may be referred to as a parity cell region.

The I/O gating circuit 290 includes a plurality of switching circuits 291a, 291b, 291c and 291d respectively connected to the first memory blocks 311, 312, ..., 313 and the second memory block 314.

The on-die ECC engine 400 may be connected to the switching circuits 291a, 291b, 291c and 291d through first data lines GIO and second data lines EDBIO. The control logic circuit 210 may receive the command CMD and the address ADDR and may decode the command CMD to generate the first control signal CTL1 for controlling the switching circuits 291a, 291b, 291c and 291d the second control signal CTL2 for controlling the on-die ECC engine 400 and the third control signal CTL3 for controlling the link ECC engine 500.

Based on a write command, the link ECC engine 500 may receive a codeword CW1 including the main data MD1 and the link parity data LPRT1, may perform an ECC decoding on the main data MD1 based on the link parity data LPRT1 to correct an error bit in the main data MD1 and to recover the main data MD1 and may provide the main data MD1 to the on-die ECC engine 400. As mentioned above, the link ECC engine 500 may generate the first syndrome including a plurality of syndrome bits based on the codeword CW1 and the first parity check matrix, may generate the decoding status flag DSF1 indicating whether the transmission error, is detected in the codeword CW1 using a characteristic of the first syndrome based on the regularity of the first parity check matrix while decoding the first syndrome, may correct an error bit of the codeword CW1 based on the decoded first syndrome, and may transmit the decoding status flag DSF1 to the memory controller 100.

The on-die ECC engine 400, based on the second control signal CTL2, may perform an ECC encoding on the main data MD1 to generate a parity data PRT and may provide the I/O gating circuit 290 with a codeword CW2 including the main data MD1 and the parity data PRT.

The control logic circuit 210 may provide the first control signal CTL1 to the I/O gating circuit 290 such that the codeword CW2 is to be stored in a sub-page of the target page in the first bank array 310a.

When the command CMD designates a read operation, the control logic circuit 210 may provide the first control signal CTL1 to the I/O gating circuit 290 such that the codeword CW2 stored in the sub-page of the target page in the first bank array 310a is provided to the on-die ECC engine 400.

The on-die ECC engine 400 may perform an ECC decoding on the main data MD1 and the parity data PRT in the codeword CW2, may correct an error bit in the codeword CW2 to output the (recovered) main data MD1 to the link ECC engine 500.

The link ECC engine 500 may perform an ECC encoding on the main data MD1 to generate the link parity data LPRT1 and may transmit the codeword CW1 including the main data MD1 and the link parity data LPRT1 to the memory controller 100.

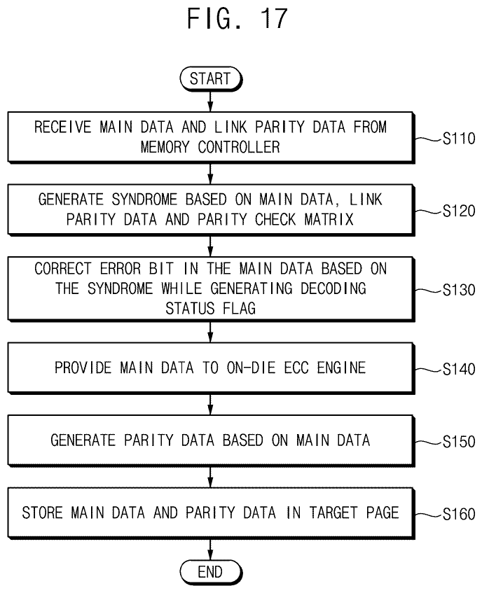

FIG. 17 is a flow chart illustrating a method of operating a semiconductor memory device according to example embodiments.

Referring to FIGS. 4 through 17, there is provided a method of operating a semiconductor memory device 200 that includes a memory cell array 310, an on-die ECC engine 400 and a link ECC engine 500.

According to the method, the link ECC engine 500 receives the main data MD11 and the link parity data LPRT11 from the memory controller 100 (operation S110). The link ECC decoder 520 in the link ECC engine 500 generates the first syndrome SDR1 based on the main data MD11, the link parity data LPRT11 and the parity check matrix PCM (operation S120).

The link ECC decoder 520 generates the decoding status flag DSF1 based on the first syndrome SDR1 while correcting a transmission error, that is correctable, of the main data MD11 based on the first syndrome SDR1 (operation S130). The link ECC decoder 520 provides the on-die ECC engine 400 with the main data MD11 that is corrected (operation S140).

The on-die ECC engine 400 generates the parity data PRT based on the main data MD11 (operation S150), and stores the main data MD11 and the parity data PRT in a target page of the memory cell array 310 (operation S160).

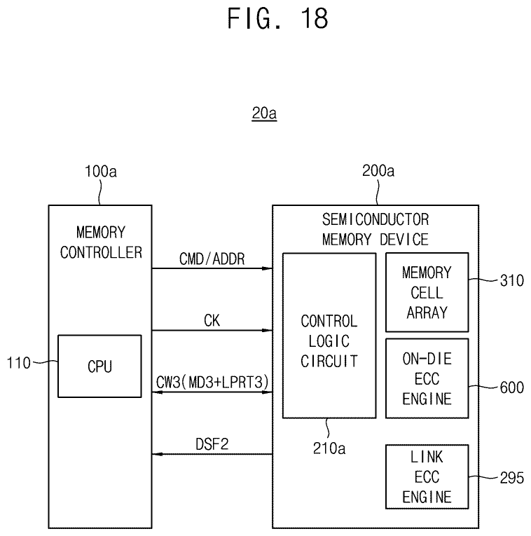

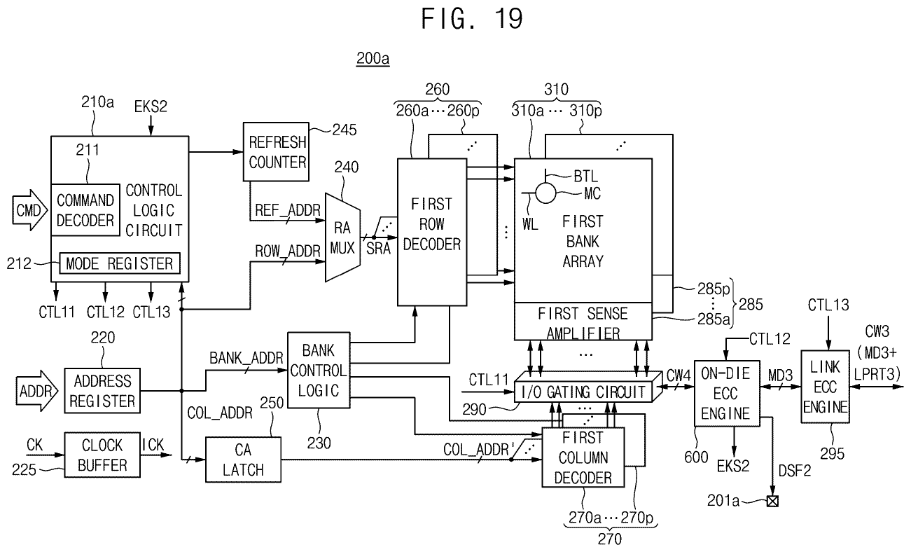

FIG. 18 is a block diagram illustrating a memory system according to example embodiments.

In FIG. 18, descriptions repeated with FIG. 1 will be omitted for convenience of explanation. Referring to FIG. 18, a memory system 20a may include a memory controller 100a and a semiconductor memory device 200a.

In some embodiments, the semiconductor memory device 200a may be a memory device including dynamic memory cells such as a DRAM, or a LP DDR6 SDRAM.

The memory controller 100a may transmit a command CMD and an address (signal) ADDR to the semiconductor memory device 200a, may transmit a clock signal CK to the semiconductor memory device 200a, may transmit a codeword CW3 including a main data MID3 and a link parity data LPRT3 to the semiconductor memory device 200a, may receive the codeword CW3 from the semiconductor memory device 200a, and may receive a decoding status flag DSF2 from the semiconductor memory device 200a.

The memory controller 100a may include a CPU 110 and the CPU 110 may control overall operation of the memory controller 100a.

The semiconductor memory device 200a may include a memory cell array 310 that stores the main data MD, an on-die ECC engine 600, a link ECC engine 295 and a control logic circuit 210a.

The link ECC engine 295, in a write operation based on a write command from the memory controller 100a, may receive the codeword CW3, may correct a transmission error, which occurs during the codeword CW3 is being transmitted from the memory controller 100a, of the main data MD3 by performing a first ECC decoding on the main data MD3 based on the link parity data LPRT3 and may provide the main data MD3, which is corrected, to the on-die ECC engine 600.

The on-die ECC engine 600 may generate a parity data by performing a first ECC encoding on the main data MD3 and may store a codeword including the main data MID3 and the parity data in a target page of the memory cell array 310.

The on-die ECC engine 600, in a read operation based on a read command from the memory controller 100a, may read a codeword including the main data MD3 and the parity data from the target page of the memory cell array 310, and may correct an error bit, which is correctable, in the main data MD3 by performing a second ECC decoding on the main data MID3 based on the parity data. When the on-die ECC engine 600 performs the second ECC decoding, the on-die ECC engine 600 may generate a first syndrome including a plurality of syndrome bits based on the read codeword and a parity check matrix that is based on a second ECC, may generate the decoding status flag DSF2 indicating whether an error is detected in the read codeword using a characteristic of the first syndrome based on a regularity of the parity check matrix while decoding the first syndrome, may correct an error bit of the read codeword based on the decoded first syndrome, may provide the main data of the codeword, which is corrected, to the link ECC engine 295, and may transmit the decoding status flag DSF2 to the memory controller 100a.

The link ECC engine 295 may generate a link parity data LPRT3 by performing a second ECC encoding on the main data MD3 received from the on-die ECC engine 600 and may transmit a codeword CW3 including the main data MD3 and the link parity data LPRT3 to the memory controller 100a.

FIG. 19 is a block diagram illustrating an example of the semiconductor memory device in the memory system of FIG. 18 according to example embodiments.

In FIG. 19, descriptions repeated with FIG. 4 will be omitted for convenience of explanation.

Referring to FIG. 19, the semiconductor memory device 200a may include the control logic circuit 210a, an address register 220, a bank control logic 230, a refresh counter 245, a row address multiplexer RA MUX 240, a column address latch 250, a row decoder 260, a column decoder 270, the memory cell array 310, a sense amplifier unit 285, an I/O gating circuit 290, the on-die ECC engine 600, a clock buffer 225 and the link ECC engine 295.

In a read operation, codeword CW4 read from a selected one bank array of the first through sixteenth bank arrays 310a~310p is sensed by a sense amplifier coupled to the selected one bank array from which the data is to be read, and is stored in the read data latches. The codeword CW4 stored in the read data latches may be provided to the link ECC engine 295 as a main data MD3 after the second ECC decoding is performed on the codeword CW4 by the on-die ECC engine 600. The link ECC engine 295 may generate a link parity data LPRT3 by performing a second ECC encoding on the main data MID3 and ay transmit a codeword CW3 including the main data MD3 and the link parity data LPRT3 to the memory controller 100a.

When the on-die ECC engine 600 performs the second ECC decoding, the on-die ECC engine 600 may generate a first syndrome including a plurality of syndrome bits based on the codeword CW4 and the parity check matrix that is based on a second ECC, may generate the decoding status flag DSF2 indicating whether an error is detected in the read codeword using a characteristic of the first syndrome based on a regularity of the parity check matrix while decoding the first syndrome, may correct an error bit of the read codeword CW4 based on the decoded first syndrome, may provide the main data of the codeword, which is corrected, to the link ECC engine 295, and may transmit the decoding status flag DSF2 to the memory controller 100a through an alert pin 201a. The on-die ECC engine 600 may provide the control logic circuit 210a with an error kind signal EKS2 indicating a type of the error detected in the codeword CW4.

In the write operation, the link ECC engine 295 may receive the codeword CW3 including the link parity data LPRT3 and the main data MD3 to be written in a selected one bank array of the first through sixteenth bank arrays 310a~310p from the memory controller 100a. The link ECC engine 295 may provide the main data MD3 to the on-die ECC engine 600 by performing a first ECC decoding on the main data MD3 based on the link parity data LPRT3 to correct at least one error bit occurring during the codeword CW3 is being transmitted. The on-die ECC engine 600 may perform a first ECC encoding on the main data MD3 to generate parity bits (or parity data), and the on-die ECC engine 600 may provide the codeword CW4 including main data MD3 and the parity bits to the I/O gating circuit 290. The I/O gating circuit 290 may write the codeword CW4 in a target page in the selected one bank array through the write drivers.

The control logic circuit 210a may control operations of the semiconductor memory device 200a. For example, the control logic circuit 210a may generate control signals for the semiconductor memory device 200a in order to perform a write operation, a read operation or a refresh operation. The control logic circuit 210a may include a command decoder 211 that decodes the command CMD received from the memory controller 100a and a mode register 212 that sets an operation mode of the semiconductor memory device 200a.

For example, the command decoder 211 may generate the control signals corresponding to the command CMD by decoding a write enable signal, a row address strobe signal, a column address strobe signal, a chip select signal, etc. The control logic circuit 210a may generate a first control signal CTL11 for controlling the I/O gating circuit, the second control signal CTL12 for controlling the on-die ECC engine 600 and a third control signal CTL13 for controlling the link ECC engine 295.

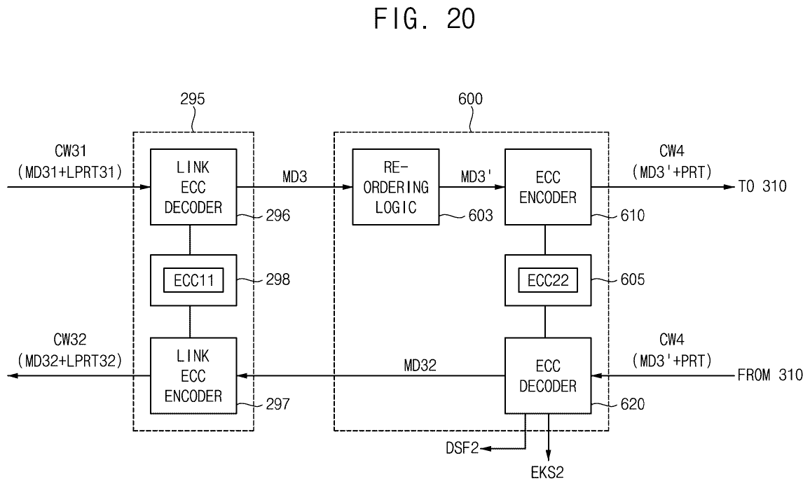

FIG. 20 illustrates a portion of the semiconductor memory device of FIG. 19.

In FIG. 20, the link ECC engine 295 and the on-die ECC engine 600 of the semiconductor memory device 200a are illustrated.

Referring to FIG. 20, the link ECC engine 295 may include a link ECC decoder 296, a link ECC encoder 297 and a first memory 298. The first memory 298 may store a first ECC ECC11.

The on-die ECC engine 600 may include a re-ordering logic 603, a second memory 605, an ECC encoder 610 and an ECC decoder 620. The second memory 605 may store a second ECC ECC22.

The link ECC decoder 296, in the write operation, may receive a first codeword CW31 including a first main data MD31 and a first link parity data LPRT31, may correct a transmission error of the first main data MD31 by performing a first ECC decoding on the first main data MD11 based on the first link parity data LPRT31 and the first ECC ECC11 and may provide a main data MD3, which is corrected, to the re-ordering logic 603.

The re-ordering logic 603 may generate an intermediate main data MD3′ by re-ordering data bits of the main data and may provide the intermediate main data MD3′ to the ECC encoder 610.

The ECC encoder 610 may generate the parity data PRT by performing a first ECC encoding on the intermediate main data MD3′ based on the second ECC ECC22 and may store the codeword CW4 including the intermediate main data MD3′ and the parity data PRT in the target page of the memory cell array 310.

The ECC decoder 620, in a read operation, may read the codeword CW4 including the intermediate main data MD3′ and the parity data PRT from the target page of the memory cell array 310, may generate a second main data MD32 by performing a second ECC decoding on the codeword CW4 (e.g., the intermediate main data MD3′) based on the second ECC ECC22 to correct an error bit, which is correctable, in the intermediate main data MD3′ and may provide the second main data MD32 to the link ECC encoder 297.

When the ECC decoder 620 performs the second ECC decoding, the ECC decoder 620 may generate a syndrome including a plurality of syndrome bits based on the codeword CW4 and a parity check matrix that is based on the second ECC ECC22, may generate the decoding status flag DSF2 indicating whether an error is detected in the read codeword CW4 using a characteristic of the syndrome based on a regularity of the parity check matrix while decoding the syndrome, may correct an error bit of the read codeword CW4 based on the decoded first syndrome, may provide the main data MD32 of the codeword CW4, which is corrected, to the link ECC encoder 297, and may transmit the decoding status flag DSF2 to the memory controller 100a. The ECC decoder 620 may provide the control logic circuit 210a with an error kind signal EKS2 indicating a type of the error detected in the codeword CW4.

The link ECC encoder 297 may generate a second link parity data LPRT32 by performing a second ECC encoding on the second main data MD32 based on the first ECC ECC11 and may transmit the codeword CW32 including the second main data MD32 and the second link parity data LPRT32 to the memory controller 100a.

Although not illustrated in FIG. 20, the on-die ECC engine 600 may further include a second re-ordering logic disposed between the memory cell array 310 and the ECC decoder 620. The second re-ordering logic may generate an intermediate codeword by re-ordering data bits of the codeword CW4 and may provide the intermediate codeword to the ECC decoder 620.

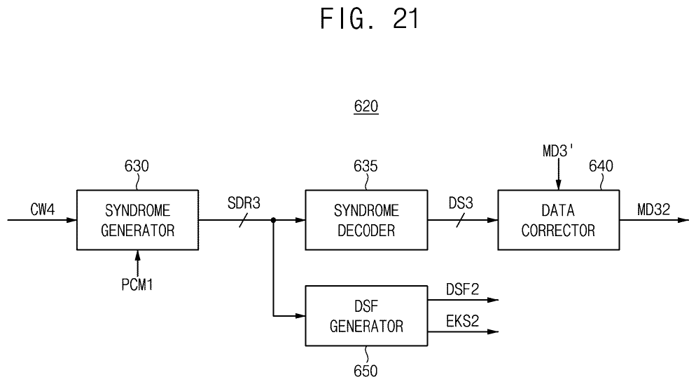

FIG. 21 is a block diagram illustrating an example of the ECC decoder in the on-die ECC engine in FIG. 20 according to example embodiments.

Referring to FIG. 21, the ECC decoder 620 may include a syndrome generator 630, a syndrome decoder 635, a data corrector 640 and a DSF generator 650.

The syndrome generator 630 may generate a syndrome SDR3 based on a parity check matrix PCM1 and the data bits of the codeword CW4. The syndrome generator 630 may generate the syndrome SDR3 by performing a matrix-multiplication operation on the codeword CW4 and the parity check matrix PCM1.

The syndrome decoder 635 may generate a decoding signal DS3 indicating a position of an error in the intermediate main data MD3′ of the codeword CW4 by decoding the syndrome SDR3 and may provide the decoding signal DS3 to the data corrector 640.

The data corrector 640 may generate the corrected main data MD32 by correcting an error bit of intermediate main data MD3′ in the codeword CW4 based on the decoding signal DS3. The data corrector 640 may provide the corrected main data MD32 to the link ECC encoder 297.

The DSF generator 650 may generate the decoding status flag DSF2 and the error kind signal EKS2 based on the syndrome SDR2 in parallel with an operation of the syndrome decoder 635 (e.g., in parallel with the syndrome decoder 635 generating the decoding signal DS3), may transmit the decoding status flag DSF2 to the memory controller 100a and may provide the error kind signal EKS2 to the control logic circuit 210a. The DSF generator 650 may divide the plurality of syndrome bits of the syndrome SDR3 into a plurality of sets, may generate counted values by counting a number of syndrome bits having a logic high levels in each of the plurality of set and may generate the decoding status flag DSF2 based on the counted values.

The parity check matrix PCM1 may be similar with the first parity check matrix PCM in FIGS. 11A through 11L. The parity check matrix PCM1 may be obtained by replacing the link parity bits L0~L15 of the first parity check matrix PCM with parity bits of the parity data PRT.

As mentioned above, in parallel with an operation of the syndrome decoder 635, the DSF generator 650 may divide the syndrome bits of the first syndrome SDR3 into the plurality of sets, may generate counted values by counting a number of syndrome bits having a logic high levels in each of the plurality of sets and may generate the decoding status flag DSF2 based on the counted values. When the DSF generator 650 generates the decoding status flag DSF2, the DSF generator 650 does not use a result of the syndrome decoding. Therefore, the ECC decoder 620 may reduce the decoding latency and may reduced occupied circuit area associated with the ECC decoder 620.

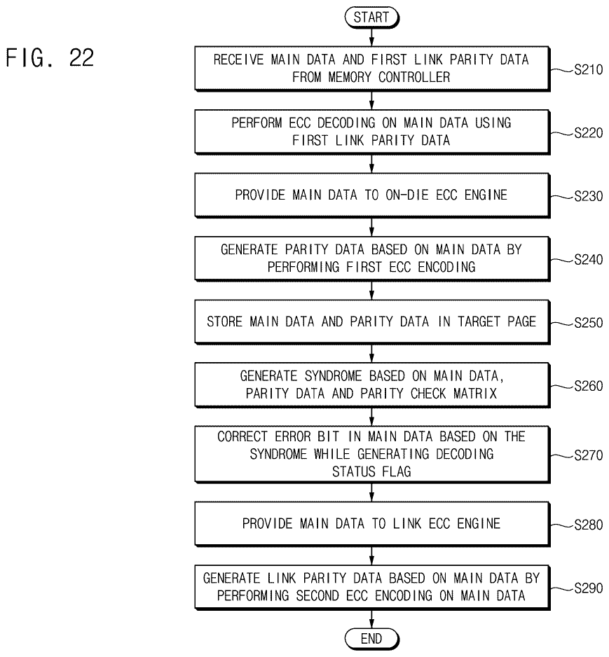

FIG. 22 is a flow chart illustrating a method of operating a semiconductor memory device according to example embodiments.

Referring to FIGS. 18 through 22, there is provided a method of operating a semiconductor memory device 200a that includes a memory cell array 310, an on-die ECC engine 600 and a link ECC engine 295.

According to the method, the link ECC engine 295 receives the first main data MID31 and the first link parity data LPRT31 from the memory controller 100a (operation S210). The link ECC decoder 296 in the link ECC engine 295 performs a first ECC decoding on the first main data MD31 based on the first link parity data LPRT31 to correct a transmission error of the first main data MD31 (operation S220) and provides the first main data MID31 to the on-die ECC engine 600 (operation S230).

The ECC encoder 610 in the on-die ECC engine 600 generates the parity data PRT based on the first main data MD31 (operation S240), and stores the first main data MD31 and the parity data PRT in a target page of the memory cell array 310 (operation S250).

In a read operation, the ECC decoder 620 in the on-die ECC engine 600 reads the first main data MD31 and the parity data PRT from the target page of the memory cell array 310, generates the syndrome SDR3 based on the parity check matrix PCM1, the first main data MD31 and the parity data PRT (operation S260), generates the decoding status flag DSF2 based on the syndrome SDR3 while correcting an error bit, which is correctable, of the first main data MD31 to generate the corrected main data MD32 based on the syndrome SDR3 (operation S270), and provides the corrected main data MD32 to the link ECC engine 295 (operation S280).

The link ECC encoder 297 in the link ECC engine 295 generates the second link parity data LPRT32 by performing a second ECC encoding on the corrected main data MD32 (operation S290) and transmits the corrected main data MD32 and the second link parity data LPRT32 to the memory controller 100a.

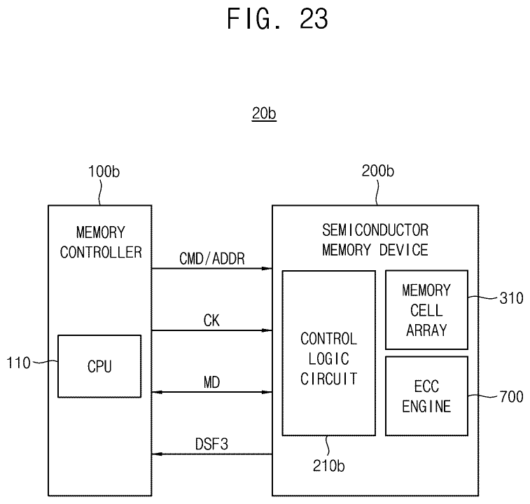

FIG. 23 is a block diagram illustrating a memory system according to example embodiments.

In FIG. 23, descriptions repeated with FIG. 1 will be omitted for convenience of explanation.

Referring to FIG. 23, a memory system 20b may include a memory controller 100b and a semiconductor memory device 200b.

In some embodiments, the semiconductor memory device 200b may be a memory device including dynamic memory cells such as a DRAM, or a LP DDR6 SDRAM.

The memory controller 100b may transmit a command CMD and an address (signal) ADDR to the semiconductor memory device 200b, may transmit a clock signal CK to the semiconductor memory device 200b, may transmit a main data MD to the semiconductor memory device 200a, may receive the main data MD from the semiconductor memory device 200b, and may receive a decoding status flag DSF3 from the semiconductor memory device 200b.

The memory controller 100b may include a CPU 110 and the CPU 110 may control overall operation of the memory controller 100b.

The semiconductor memory device 200b may include a memory cell array 310 that stores the main data MD, an ECC engine 700 and a control logic circuit 210b.

The ECC engine 700, in a write operation based on a write command from the memory controller 100b, may receive the main data MD, may generate a parity data by performing an ECC encoding on the main data MD and may store the main data MD and the parity data in a target page of the memory cell array.

The ECC engine 700, in a read operation based on a read command from the memory controller 100b, may read a codeword including the main data MD and the parity data from the target page of the memory cell array 310, and may correct an error bit, which is correctable, in the main data MD by performing an ECC decoding on the main data MD based on the parity data. When the ECC engine 700 performs the ECC decoding, the ECC engine 700 may generate a syndrome including a plurality of syndrome bits based on the read codeword and a parity check matrix that is based on an ECC, may generate the decoding status flag DSF3 indicating whether an error is detected in the read codeword using a characteristic of the syndrome based on a regularity of the parity check matrix while decoding the syndrome, may correct an error bit of the read codeword based on the decoded syndrome, and may transmit the main data of the corrected codeword and the decoding status flag DSF3 to the memory controller 100b.

Therefore, the ECC engine 700 generates the decoding status flag DSF3 by using only the syndrome, and thus, the ECC engine 700 may reduce the decoding latency and may reduced occupied circuit area associated with the ECC engine 700.

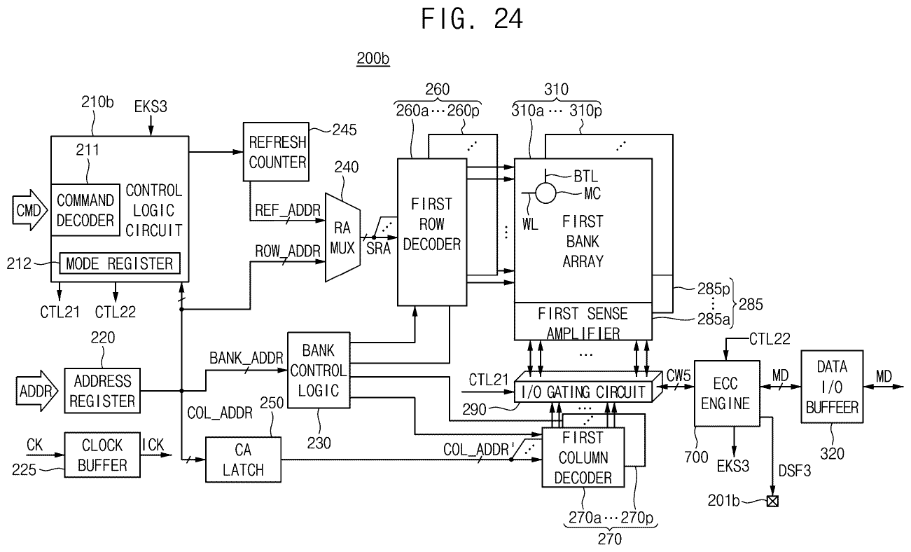

FIG. 24 is a block diagram illustrating an example of the semiconductor memory device in the memory system of FIG. 23 according to example embodiments.

In FIG. 24, descriptions repeated with FIG. 4 will be omitted for convenience of explanation.

Referring to FIG. 24, the semiconductor memory device 200b may include the control logic circuit 210b, an address register 220, a bank control logic 230, a refresh counter 245, a row address multiplexer RA MUX 240, a column address latch 250, a row decoder 260, a column decoder 270, the memory cell array 310, a sense amplifier unit 285, an I/O gating circuit 290, the ECC engine 700, a clock buffer 225 and a data I/O buffer 320.

In a read operation, codeword CW5 read from a selected one bank array of the first through sixteenth bank arrays 310a~310p is sensed by a sense amplifier coupled to the selected one bank array from which the data is to be read, and is stored in the read data latches. The codeword CW5 stored in the read data latches may be provided to the data I/O buffer as a main data MD after the second ECC decoding is performed on the codeword CW5 by the ECC engine 700. The data I/O buffer 320 may transmit the main data MD to the memory controller 100b.

When the ECC engine 700 performs the ECC decoding, the ECC engine 700 may generate a syndrome including a plurality of syndrome bits based on the read codeword and a parity check matrix that is based on an ECC, may generate the decoding status flag DSF3 indicating whether an error is detected in the read codeword using a characteristic of the syndrome based on a regularity of the parity check matrix while decoding the syndrome, may correct an error bit of the read codeword based on the decoded syndrome, may provide the main data MD of the corrected codeword to the data I/O buffer 320, and may transmit the decoding status flag DSF3 to the memory controller 100b through an alert pin 201b. In addition, the ECC engine 700 may provide the control logic circuit 210b with an error kind signal EKS3 indicating a type of the error detected in the codeword CW5.

In the write operation, the data I/O buffer 320 may receive the main data MD to be written in a selected one bank array of the first through sixteenth bank arrays 310a~310p from the memory controller 100b. The data I/O buffer 320 may provide the main data MD to the ECC engine 700. The ECC engine 700 may perform an ECC encoding on the main data MD to generate parity bits (or parity data), and the ECC engine 700 may provide the codeword CW5 including main data MD and the parity bits to the I/O gating circuit 290. The I/O gating circuit 290 may write the codeword CW5 in a target page in the selected one bank array through the write drivers.

The control logic circuit 210b may control operations of the semiconductor memory device 200b. For example, the control logic circuit 210b may generate control signals for the semiconductor memory device 200b in order to perform a write operation, a read operation or a refresh operation. The control logic circuit 210b may include a command decoder 211 that decodes the command CMD received from the memory controller 100b and a mode register 212 that sets an operation mode of the semiconductor memory device 200b.

For example, the command decoder 211 may generate the control signals corresponding to the command CMD by decoding a write enable signal, a row address strobe signal, a column address strobe signal, a chip select signal, etc. The control logic circuit 210b may generate a first control signal CTL21 for controlling the I/O gating circuit, and a second control signal CTL22 for controlling the ECC engine 700.

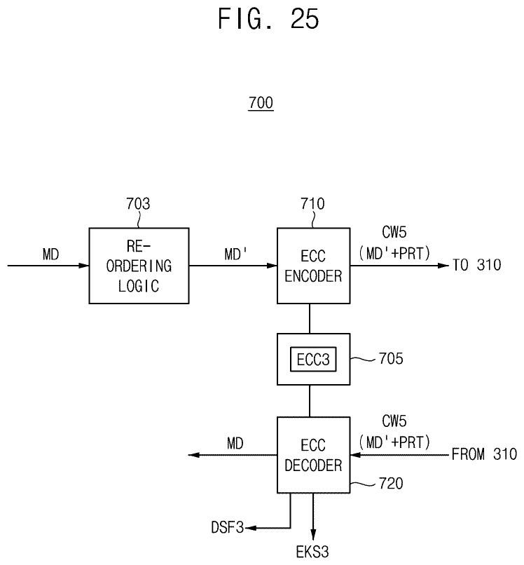

FIG. 25 is a block diagram illustrating an example of the ECC engine of the semiconductor memory device of FIG. 24 according to example embodiments.

Referring to FIG. 25, the ECC engine 700 may include a re-ordering logic 703, a memory 705, an ECC encoder 710 and an ECC decoder 720. The memory 705 may store an ECC ECC3.

The re-ordering logic 603 may generate an intermediate main data MD′ by re-ordering data bits of the main data MD and may provide the intermediate main data MD′ to the ECC encoder 710.

The ECC encoder 710 may generate the parity data PRT by performing an ECC encoding on the intermediate main data MD′ based on the ECC ECC3 and may store the codeword CW5 including the intermediate main data MD′ and the parity data PRT in the target page of the memory cell array 310.

The ECC decoder 720, in a read operation, may read the codeword CW5 including the intermediate main data MD′ and the parity data PRT from the target page of the memory cell array 310, may generate the main data MD by performing an ECC decoding on the codeword CW5 based on the ECC ECC3 to correct an error bit, which is correctable, in the intermediate main data MD′ and may provide the main data MD to the data I/O buffer 320.

When the ECC decoder 720 performs the ECC decoding, the ECC decoder 720 ECC may generate a syndrome including a plurality of syndrome bits based on the codeword CW5 and a parity check matrix that is based on the ECC ECC3, may generate the decoding status flag DSF3 indicating whether an error is detected in the read codeword CW5 using a characteristic of the syndrome based on a regularity of the parity check matrix while decoding the syndrome, may correct an error bit of the read codeword CW5 based on the decoded syndrome, may provide the main data MD of the codeword CW5, which is corrected, to the data I/O buffer 320, and may transmit the decoding status flag DSF3 to the memory controller 100b. The ECC decoder 720 may provide the control logic circuit 210b with an error kind signal EKS3 indicating a type of the error detected in the codeword CW5.

Although not illustrated in FIG. 25, the ECC engine 700 may further include a second re-ordering logic disposed between the memory cell array 310 and the ECC decoder 720. The second re-ordering logic may generate an intermediate codeword by re-ordering data bits of the codeword CW5 and may provide the intermediate codeword to the ECC decoder 720.

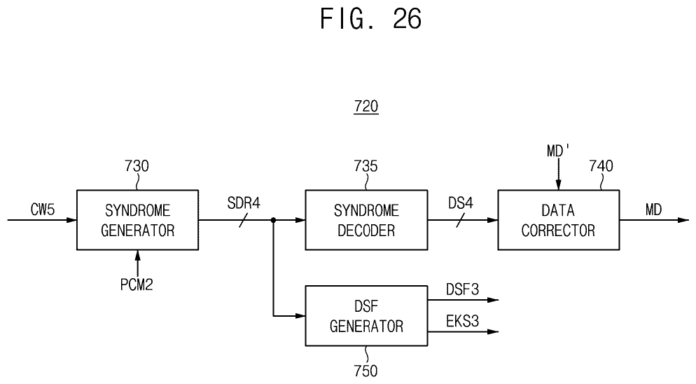

FIG. 26 is a block diagram illustrating an example of the ECC decoder in the ECC engine in FIG. 25 according to example embodiments.

Referring to FIG. 26, the ECC decoder 720 may include a syndrome generator 730, a syndrome decoder 735, a data corrector 740 and a DSF generator 750.

The syndrome generator 730 may generate a syndrome SDR4 based on a parity check matrix PCM2 and the data bits of the codeword CW5. The syndrome generator 730 may generate the syndrome SDR4 by performing a matrix-multiplication operation on the codeword CW5 and the parity check matrix PCM2.

The syndrome decoder 735 may generate a decoding signal DS4 indicating a position of an error in the intermediate main data MD′ of the codeword CW5 by decoding the syndrome SDR4 and may provide the decoding signal DS4 to the data corrector 740.

The data corrector 740 may generate the corrected main data MD by correcting an error bit of intermediate main data MD′ in the codeword CW5 based on the decoding signal DS4. The data corrector 740 may provide the corrected main data MD to the data I/O buffer 320.

The DSF generator 750 may generate the decoding status flag DSF3 and the error kind signal EKS3 based on the syndrome SDR4 in parallel with an operation of the syndrome decoder 735 (e.g., in parallel with the syndrome decoder 735 generating the decoding signal DS4), may transmit the decoding status flag DSF3 to the memory controller 100b and may provide the error kind signal EKS3 to the control logic circuit 210b. The DSF generator 750 may divide the plurality of syndrome bits of the syndrome SDR4 into a plurality of sets, may generate counted values by counting a number of syndrome bits having a logic high levels in each of the plurality of set and may generate the decoding status flag DSF3 based on the counted values.

The parity check matrix PCM2 may be similar with the first parity check matrix PCM in FIGS. 11A through 11L. The parity check matrix PCM2 may be obtained by replacing the link parity bits L0~L15 of the first parity check matrix PCM with parity bits of the parity data PRT.

As mentioned above, in parallel with an operation of the syndrome decoder 735, the DSF generator 750 may divide the syndrome bits of the first syndrome SDR4 into the plurality of sets, may generate counted values by counting a number of syndrome bits having a logic high levels in each of the plurality of sets and may generate the decoding status flag DSF3 based on the counted values. Because when the DSF generator 750 generates the decoding status flag DSF3, the DSF generator 750 does not use a result of the syndrome decoding, the ECC decoder 720 may reduce the decoding latency and may reduced occupied circuit area associated with the ECC decoder 720.

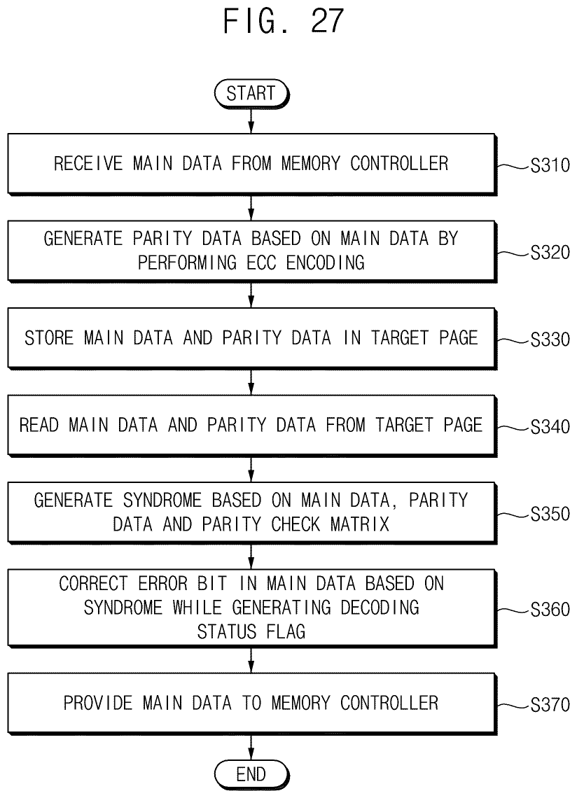

FIG. 27 is a flow chart illustrating a method of operating a semiconductor memory device according to example embodiments.

Referring to FIGS. 23 through 27, there is provided a method of operating a semiconductor memory device 200b that includes a memory cell array 310 and an ECC engine 700.

According to the method, in a write operation, the ECC engine 700 receives the main data MD from the memory controller 100b (operation S310). The ECC encoder 710 in the ECC engine 700 generates the parity data PRT based on the main data MD (operation S320), and stores the main data MD and the parity data PRT in a target page of the memory cell array 310 (operation S320).

In a read operation, the ECC decoder 720 in the ECC engine 700 reads the main data MID and the parity data PRT from the target page of the memory cell array 310 (operation S340), may generate the syndrome SDR4 based on the parity check matrix PCM2, the main data MD and the parity data PRT (operation S350), generates the decoding status flag DSF3 based on the syndrome SDR4 while correcting an error bit, which is correctable, of the main data MD to generate the corrected main data MD based on the syndrome SDR4 (operation S360), and transmit the corrected main data MD to the memory controller (operation S370).

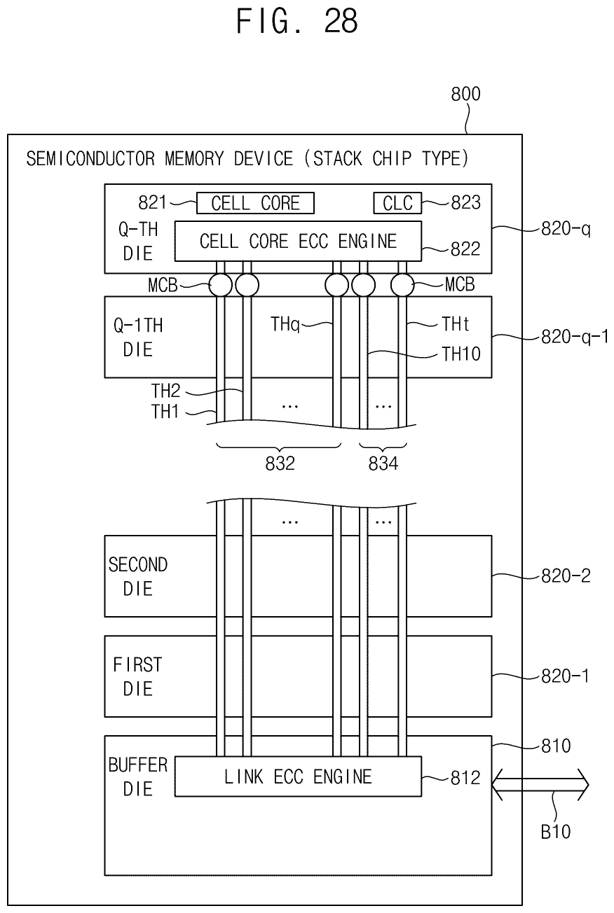

FIG. 28 is a block diagram illustrating a semiconductor memory device according to example embodiments.

Referring to FIG. 28, a semiconductor memory device 800 may include at least one buffer die 810 and a plurality of memory dies 820-1, 820-2, ..., 820-q providing a soft error analyzing and correcting function in a stacked chip structure. Here, q is an integer greater than three.

The plurality of memory dies 820-1, 820-2, ..., 820-q are stacked on the at least one buffer die 810 and conveys data through a plurality of through silicon via (TSV) lines.

Each of the memory dies 820-1, 820-2, ..., 820-q may include a cell core 821 including a memory cell array, a cell core ECC engine 822 which generates transmission parity data based on transmission data to be sent to the at least one buffer die 810 and a control logic circuit CLC 823. The cell core ECC engine 822 may employ the on-die ECC engine 400 of FIG. 6.

The at least one buffer die 810 may include a link ECC engine 812.

The link ECC engine 812 may employ the link ECC engine 500 in FIG. 6. Therefor, the link ECC engine 812, in the write operation, may generate a syndrome based on a parity check matrix and a codeword and may generate a decoding status flag indicating whether a transmission error is detected in the codeword, based on a characteristic of the syndrome which is based on a regularity of the parity check matrix while decoding the syndrome.

The semiconductor memory device 800 may be a stack chip type memory device or a stacked memory device which conveys data and control signals through the TSV lines. The TSV lines may be also called ‘through electrodes’.

A data TSV line group 832 which is formed at one memory die 820-q may include TSV lines TH1, TH2 to THq, and a parity TSV line group 834 may include TSV lines TH10 toTHt.

The TSV lines TH1, TH2 to THq of the data TSV line group 832 and the parity TSV lines TH10 toTHt of the parity TSV line group 834 may be connected to micro bumps MCB which are correspondingly formed among the memory dies 820-1, 820-2, ..., 820-q.

Each of the memory dies 820-1, 820-2, ..., 820-q may include DRAM cells each including at least one access transistor and one storage capacitor.

The semiconductor memory device 800 may have a three-dimensional (3D) chip structure or a 2.5D chip structure to communicate with the host through a data bus B10. The at least one buffer die 810 may be connected with the memory controller through the data bus B10.

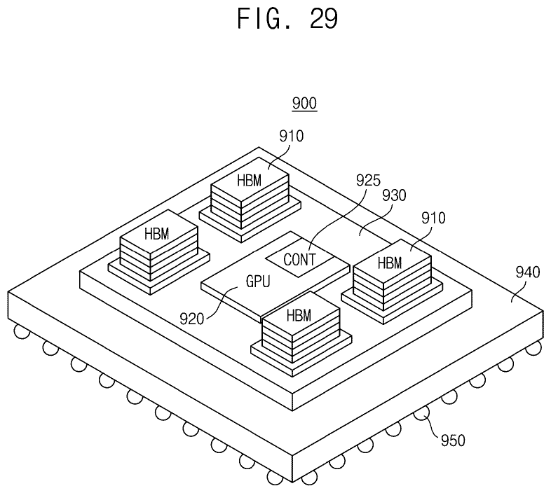

FIG. 29 is a diagram illustrating a semiconductor package including the stacked memory device, according to example embodiments.

Referring to FIG. 29, a semiconductor package 900 may include one or more stacked memory devices 910 and a graphic processing unit (GPU) 920. The GPU 920 may include a memory controller CONT 925.

The stacked memory devices 910 and the GPU 920 may be mounted on an interposer 930, and the interposer on which the stacked memory devices 910 and the GPU 920 are mounted may be mounted on a package substrate 940. The package substrate 940 may be mounted on solder balls 950. The memory controller 925 may employ the memory controller 100 in FIG. 1.

Each of the stacked memory devices 910 may be implemented in various forms, and may be a memory device in a high bandwidth memory (HBM) form in which a plurality of layers are stacked. Accordingly, each of the stacked memory devices 910 may include at least one buffer die and a plurality of memory dies. Each of the memory dies may include a memory cell array, an on-die ECC engine and a control logic circuit. The at least one buffer die may include a link ECC engine.

The plurality of stacked memory devices 910 may be mounted on the interposer 930, and the GPU 920 may communicate with the plurality of stacked memory devices 910. For example, each of the stacked memory devices 910 and the GPU 920 may include a physical region, and communication may be performed between the stacked memory devices 910 and the GPU 920 through the physical regions.

As mentioned above, according to example embodiments, in the semiconductor memory device, the link ECC engine or the on-die ECC engine, may generate the syndrome including a plurality of syndrome bits based on a codeword and a parity check matrix that is based on an ECC, and may generate a decoding status flag indicating whether a transmission error is detected in the codeword, based on a characteristic of the syndrome which is based on a regularity of the parity check matrix while decoding the syndrome. When the decoding status flag is generated, a result of the syndrome decoding is not used, and thus, the link ECC engine or the on-die ECC engine may reduce the decoding latency and may reduced occupied circuit area associated with the ECC decoding.

Aspects of the present disclosure may be applied to systems using semiconductor memory devices that employ a link ECC engine and/or an on-die ECC engine and a plurality of volatile memory cells.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present disclosure. Accordingly, all such modifications are intended to be included within the scope of the present disclosure as defined in the claims.

1. A semiconductor memory device comprising:
a memory cell array including a plurality of memory cells coupled to a plurality of word-lines and a plurality of bit-lines;
an on-die error correction code (ECC) engine;
a link ECC engine; and
a control logic circuit configured to control the on-die ECC engine and the link ECC engine,
wherein the link ECC engine, in a write operation, is configured to:
receive a first codeword including a first main data and a first link parity data from a memory controller external to the semiconductor memory device;
generate a first syndrome including a plurality of syndrome bits based on the first codeword and a first parity check matrix that is based on a first ECC;
generate a decoding status flag indicating whether a transmission error is detected in the first codeword using a characteristic of the first syndrome based on a regularity of the first parity check matrix while decoding the first syndrome, the transmission error occurring during the first codeword is being transmitted from the memory controller;
correct an error bit of the first codeword based on the decoded first syndrome; and
provide the first main data of the first codeword, which is corrected, to the on-die ECC engine,
wherein the on-die ECC engine, in the write operation, is configured to:
generate a parity data by performing a first ECC encoding on the first main data based on a second ECC; and
store the first main data and the parity data in a target page of the memory cell array.

2. The semiconductor memory device of claim 1, wherein the link ECC engine includes:
a link ECC decoder configured to receive the first codeword, generate the first syndrome and generate the decoding status flag; and
a memory configured to store the first ECC, and
wherein the link ECC decoder is configured to:
divide the plurality of syndrome bits into a plurality of sets;
generate counted values by counting a number of syndrome bits having a logic high levels in each of the plurality of sets; and
generate the decoding status flag based on the counted values.

3. The semiconductor memory device of claim 1,
wherein the first main data includes a plurality of data bits,
wherein the first link parity data includes a plurality of link parity bits,
wherein the first parity check matrix includes a plurality of column vectors corresponding to the plurality of data bits and the plurality of link parity bits,
wherein the plurality of column vectors include a first part of column vectors corresponding to the plurality of data bits and a second part of column vectors corresponding to the plurality of link parity bits,
wherein a number of elements having a logic high level in each of the first part of column vectors corresponds to a first value, and
wherein a number of elements having a logic high level in each of the second part of column vectors corresponds to a second value smaller than the first value.

4. The semiconductor memory device of claim 3,
wherein the link ECC decoder is configured to divide the plurality of syndrome bits into a plurality of sets,
wherein the plurality of sets include a first set, a second set, a third set and a fourth set, and
wherein the first value is three and the second value is one.

5. The semiconductor memory device of claim 3,
wherein the link ECC decoder is configured to divide the plurality of syndrome bits into a plurality of sets and determine a type of the transmission error based on a first number, a second number and a third number,
wherein the plurality of sets include a first set, a second set, a third set and a fourth set,
wherein the first number designates a number of at least one set including two syndrome bits having a logic high level, among the first set, the second set, the third set and the fourth set,
wherein the second number designates a number of at least one set including one syndrome bit having a logic high level, among the first set, the second set, the third set and the fourth set, and
wherein the third number designates a number of at least one set including four syndrome bits having a logic low level, among the first set, the second set, the third set and the fourth set.

6. The semiconductor memory device of claim 5, wherein the link ECC decoder, in response to the third number being four, is configured to determine that the transmission error does not occur.

7. The semiconductor memory device of claim 5, wherein the link ECC decoder, in response to the third number being three, the second number being one and the first number being zero, is configured to determine that the transmission error occurs in the first link parity data.

8. The semiconductor memory device of claim 5, wherein the link ECC decoder, in response to the third number being two, the second number being one and the first number being one, is configured to determine that the transmission error, which is correctable, occurs in the first main data.

9. The semiconductor memory device of claim 5, wherein the link ECC decoder, in response to at least one of the plurality of syndrome bits having a logic high level and the first syndrome not matching respective one of the plurality of column vectors, is configured to determine that the transmission error, which is uncorrectable, occurs.

10. The semiconductor memory device of claim 2, wherein the link ECC decoder includes:
a syndrome generator configured to generate the first syndrome by performing a matrix-multiplication operation on a first intermediate codeword and the first parity check matrix, the first intermediate codeword being obtained by rearranging bits of the first codeword;
a syndrome decoder configured to generate a decoding signal by decoding the first syndrome;
a data corrector configured to generate a corrected first main data by correcting an error bit of a first main data in the first intermediate codeword; and
a decoding status flag generator configured to generate the decoding status flag and an error kind signal indicating a type of the transmission error, based on the first syndrome, the decoding status flag generator generating the decoding status flag and the error kind signal in parallel with an operation of the syndrome decoder.

11. The semiconductor memory device of claim 2, wherein the on-die ECC engine includes:
an encoding/decoding logic configured to generate the parity data by performing the first ECC encoding on the first main data, in the write operation, and generate a second syndrome by performing an ECC decoding on the first main data and the parity data read from the target page based on the second ECC, in a read operation;
an ECC decoder configured to generate a second main data by correcting an error bit of the first main data based on the second syndrome and provide the second main data to the link ECC engine; and
a second memory store the second ECC,
wherein the link ECC engine further includes a link ECC encoder, and
wherein the link ECC encoder is configured to generate a second link parity data by performing a second ECC encoding on the second main data based on the first ECC, and transmit a second codeword including the second main data and the second link parity data to the memory controller.

12. The semiconductor memory device of claim 1, wherein the link ECC engine is configured to transmit the decoding status flag to the memory controller through an alert pin of the semiconductor memory device.

13. The semiconductor memory device of claim 12, wherein the link ECC engine is configured to transition the alert pin to a logic high level when the link ECC engine determines that transmission error, which is uncorrectable, occurs based on the first syndrome.

14. A semiconductor memory device comprising:
a memory cell array including a plurality of memory cells coupled to a plurality of word-lines and a plurality of bit-lines;
an on-die error correction code (ECC) engine;
a link ECC engine; and
a control logic circuit configured to control the on-die ECC engine and the link ECC engine,
wherein the link ECC engine, in a write operation, is configured to:
receive a first codeword including a first main data and a first link parity data from a memory controller external to the semiconductor memory device;
correct a transmission error in the first codeword by performing a first ECC decoding on the first codeword based on a first ECC, the transmission error occurring during the first codeword is being transmitted from the memory controller; and
provide the first main data of the first codeword, which is corrected, to the on-die ECC engine,
wherein the on-die ECC engine, in the write operation, is configured to:
generate a parity data by performing a first ECC encoding on the first main data based on a second ECC; and
store the first main data and the parity data in a target page of the memory cell array,
wherein the on-die ECC engine, in a read operation, is configured to:
generate a syndrome including a plurality of syndrome bits based on the first main data, the parity data and a parity check matrix is based on the second ECC, the first main data and the parity data read from the target page;
generate a decoding status flag indicating whether an error is detected in the first main data and the parity data using a characteristic of the syndrome based on a regularity of the parity check matrix while decoding the syndrome;
generate a second main data by correcting an error bit of the first main data based on the decoded syndrome; and
provide the second main data to the link ECC engine.

15. The semiconductor memory device of claim 14, wherein the on-die ECC engine includes:
an ECC encoder configured to generate the parity data in the write operation;
an ECC decoder configured to, in the read operation, generate the syndrome, generate the decoding status flag, generate the second main data, and provide the second main data to the link ECC engine; and
a memory configured to store the second ECC,
wherein the ECC decoder is configured to divide the plurality of syndrome bits into a plurality of sets, generate counted values by counting a number of syndrome bits having a logic high levels in each of the plurality of sets, and generate the decoding status flag based on the counted values, and
wherein the ECC decoder is configured to transmit the decoding status flag to the memory controller through an alert pin.

16. The semiconductor memory device of claim 14,
wherein the first main data includes a plurality of data bits,
wherein the parity data includes a plurality of parity bits,
wherein the parity check matrix includes a plurality of column vectors corresponding to the plurality of data bits and the plurality of parity bits,
wherein the plurality of column vectors include a first part of column vectors corresponding to the plurality of data bits and a second part of column vectors corresponding to the plurality of parity bits,
wherein a number of elements having a logic high level in each of the first part of column vectors corresponds to a first value, and
wherein a number of elements having a logic high level in each of the second part of column vectors corresponds to a second value smaller than the first value.

17. The semiconductor memory device of claim 16,
wherein the ECC decoder is configured to divide the plurality of syndrome bits into a plurality of sets and determine a type of the error based on a first number, a second number and a third number,
wherein the plurality of sets include a first set, a second set, a third set and a fourth set,
wherein the first number designates a number of at least one set including two syndrome bits having a logic high level, among the first set, the second set, the third set and the fourth set,
wherein the second number designates a number of at least one set including one syndrome bit having a logic high level, among the first set, the second set, the third set and the fourth set, and
wherein the third number designates a number of at least one set including four syndrome bits having a logic low level, among the first set, the second set, the third set and the fourth set.

18. The semiconductor memory device of claim 17, wherein the ECC decoder, in response to the third number being two, the second number being one and the first number being one, is configured to determine that the error, which is correctable, occurs.

19. A semiconductor memory device comprising:
a memory cell array including a plurality of memory cells coupled to a plurality of word-lines and a plurality of bit-lines;
an error correction code (ECC) engine; and
a control logic circuit configured to control the ECC engine,
wherein the ECC engine, in a write operation, is configured to:
receive a first main data from a memory controller external to the semiconductor memory device;
generate a parity data by performing an ECC encoding on the first main data based on an ECC; and
store the first main data and the parity data in a target page of the memory cell array, and
wherein the ECC engine, in a read operation, is configured to:
read the first main data and the parity data form the target page;
generate a syndrome including a plurality of syndrome bits based on the first main data, the parity data and a parity check matrix that is based on the ECC;
generate a decoding status flag indicating whether an error is detected in the first main data and the parity data using a characteristic of the syndrome based on a regularity of the parity check matrix while decoding the syndrome;
generate a second main data by correcting an error bit of the first main data based on the decoded syndrome; and
transmit the second main data to the memory controller.

20. The semiconductor memory device of claim 19, wherein the ECC engine includes:
an ECC encoder configured to generate the parity data in the write operation;
an ECC decoder configured to, in the read operation, generate the syndrome, generate the decoding status flag, and generate the second main data; and
a memory configured to store the ECC,
wherein the ECC decoder is configured to divide the plurality of syndrome bits into a plurality of sets, generate counted values by counting a number of syndrome bits having a logic high levels in each of the plurality of sets, and generate the decoding status flag based on the counted values, and
wherein the ECC decoder is configured to transmit the decoding status flag to the memory controller through an alert pin.
